(19) United States
(12) Patent Application Publication
(10) Pub. No.: US 2006/0113581 A1
(43) Pub. Date: Jun. 1, 2006

(54) Semiconductor memory device

(76) Inventors: Takashi Miki, Nishinomiya-shi (JP); Hiroshige Hirano, Nara-shi (JP)

Correspondence Address: WENDEROTH, LIND & PONACK L.L.P., 2033 K. STREET, NW, SUITE 800, WASHINGTON, DC, 20006, US

(21) Appl. No.: 11/289,441

(22) Filed: Nov. 30, 2005

(30) Foreign Application Priority Data
Nov. 30, 2004 (JP) 2004-345085

(51) Int. Cl. H01L 29/94

(52) U.S. Cl. 257/306

(57) ABSTRACT

A semiconductor memory device having a memory cell array in which plural memory transistors and plural memory call capacitors, which are components of memory cells, are arranged, comprises a first wiring layer formed on the memory cell array, and a second wiring layer formed above the first wiring layer, wherein a wiring density of the first wiring layer on the memory cell array is higher than a wiring density of the second wiring layer on the memory cell array. Therefore, a hydrogen barrier property for the capacitors is improved, and an adverse effect due to stress applied to the capacitors is reduced, thereby suppressing deterioration of capacitor characteristics.

### FIELD OF THE INVENTION

The present invention relates to a semiconductor memory device and, more particularly, to that having a multilayer interconnection formed on a memory cell array.

### BACKGROUND OF THE INVENTION

A multilayer interconnection technique has been used for high-density integration in a memory such as a ferroelectric nonvolatile memory (hereinafter referred to as “FeRAM”). However, a FeRAM having a multilayer interconnection has a conventional problem that a ferroelectric material used for a ferroelectric capacitor is reduced when it is subjected to a reducing ambient including hydrogen during manufacturing of an inter-layer insulating film, a tungsten plug, and the like in the multilayer interconnection, leading to degradation in electrical characteristics of the capacitor.

In order to suppress such degradation in characteristics of the capacitor, there has been proposed a construction for protecting the capacitor, such as a hydrogen barrier protection film formed on the capacitor.

Hereinafter, a conventional semiconductor memory device having such construction will be described with reference to figures.

FIGS. 16 and 17 are diagrams for explaining a semiconductor memory device disclosed in Japanese Published Patent Application No. 2002-94021 (patent literature 1). FIG. 16 is a cross-sectional view of a main part of the semiconductor memory device in the bit line direction, and FIG. 17 is a cross-sectional view of the main part of the semiconductor memory device in the word line direction.

The semiconductor memory device 100 has a semiconductor substrate 101, and p wells 103a and 103b are formed in a memory cell area A at the surface of the semiconductor substrate 101, and further, an n well 104 is formed in a peripheral circuitry area B at the surface of the substrate 101. These wells are electrically separated by an element separation insulating film 102 which is formed at the surface of the semiconductor substrate, and n type impurity diffused areas 108a and 108b are formed at the surface of the p well 103a while a p type impurity diffused area 109 is formed at the surface of the n well 104.

In the p well 103a, the n type impurity diffused areas 108b are positioned at the both sides of the n type impurity diffused area 108a, and gate electrodes 106a and 106b are disposed on the surface of the p well 103a via a gate insulating film 105, in areas between the n type impurity diffused area 108a and the n type impurity diffused areas 108a on the left side and the right side of the area 108a, respectively. A gate electrode 106c is disposed on the surface of the n well 104 via a gate insulating film 105, in an area between two p type impurity diffused areas 109. Further, a leading electrode 107 is disposed on the element separation insulating film 102 in the peripheral circuitry area B.

Each of the gate electrodes 106a˜106c and the leading electrode 107 has a two-layer structure comprising a semiconductor film and a low-resistance film disposed on the surface of the semiconductor film, and the gate electrodes 106a and 106b disposed in the memory cell area A constitute a portion of a word line.

A first inter-layer insulating film 111 is disposed over the entire surface of the substrate on which the p wells, the n wells, the gate electrodes, and the element separation insulating film are disposed. Further, contact plugs 113a˜113e are disposed in portions of the inter-layer insulating film 111 located above the impurity diffused areas 108a, 108b, 109 and the leading electrode 107, and the contact plugs 113a˜113e connect the wiring or electrodes disposed on the inter-layer insulating film 111 with these impurity diffused areas. Further, a contact plug 113f is disposed in a portion of the inter-layer insulating film 111 located above a portion of the p well 103b, and this contact plug 113f connects the p well 103b with the wiring or the like on the inter-layer insulating film 111. In order to prevent the contact plugs from being oxidized, a silicon oxynitride film 114 and an oxidized silicon film 115 are successively disposed on the inter-layer insulating film 111. Each contact plug is formed by successively depositing a titanium film and a titanium nitride film on an inner surface of a contact hole formed through the inter-layer insulating film, and thereafter, filling the contact hole with tungsten.

A capacitor 120 comprising a lower electrode 116a, a ferroelectric film 117a, and an upper electrode 118a is disposed on a part of the oxide silicon film 115 above the element separation insulating film 102. On the capacitor 120, a first protection film 119 is disposed over the ferroelectric film 117a and the upper electrode 118a, and further, a second inter-layer insulating film 121 is disposed over the first protection film 119 and the oxide silicon film 115.

An end of a first wiring 122a disposed on the second inter-layer insulating film 121 is connected to the upper electrode 118a of the capacitor 120 via a contact hole penetrating the first protection film 119 and the second inter-layer insulating film 121, and the other end of the first wiring 122a is connected to the contact plug 113b on the impurity diffused area 108b via a contact hole penetrating the silicon oxynitride film 114, the oxidized silicon film 115, and the second inter-layer insulating film 121. Further, an end of a second wiring 122b disposed on the second inter-layer insulating film 121 is connected to the lower electrode 116a of the capacitor 120.

A second protection film 123 is disposed over the first wiring 122a, the second wiring 122b, and the first inter-layer insulating film 121, and further, a third inter-layer insulating film 124 is disposed over the second protection film 123.

This literature discloses, as shown in FIGS. 16 and 17, the construction of the semiconductor memory device 100 in which the surface of the ferroelectric capacitor 120 is covered with the first protection film 119, and the capacitor is further covered with the second protection film 123 which is positioned on the first wiring connected to the capacitor upper electrode 118a. This literature describes that, even when fabricating an insulating film or a conductive film or performing etching or the like using a reducing ambient above the ferroelectric capacitor, the ferroelectric film is protected from the reducing ambient including hydrogen by the protection film formed beneath the films to be processed, whereby the capacitor characteristics are improved.

Although the above-mentioned conventional semiconductor memory device has the construction in which the hydrogen barrier protection film is formed on the capacitor to reduce deterioration of the capacitor characteristics, if the hydrogen barrier protection film is imperfect, the capacitor characteristics deteriorate. Further, stress or the like may be applied to the capacitor, depending on the structure disposed on the hydrogen barrier protection film, leading to deterioration of the capacitor characteristics.

### SUMMARY OF THE INVENTION

The present invention is made to solve the above-described problems and has for its object to provide a semiconductor memory device which is able to improve hydrogen barrier property for the capacitor, and reduce an adverse effect due to stress applied to the capacitor, thereby reliably suppressing deterioration of the capacitor characteristics.

Other objects and advantages of the invention will become apparent from the detailed description that follows. The detailed description and specific embodiments described are provided only for illustration since various additions and modifications within the scope of the invention will be apparent to those of skill in the art from the detailed description.

According to a first aspect of the present invention, there is provided a semiconductor memory device having a memory cell array in which plural memory transistors and plural memory call capacitors, which are components of memory cells, are arranged, and the device comprises a first wiring layer formed on the memory cell array, and a second wiring layer formed above the first wiring layer, wherein a wiring density of the first wiring layer on the memory cell array is higher than a wiring density of the second wiring layer on the memory cell array. Therefore, the wiring density of the wiring layer which is close to the capacitor and has a hydrogen barrier effect is increased, whereby an effect of suppressing deterioration of capacitor characteristics due to hydrogen can be enhanced. Further, in this wiring structure, the effect of suppressing deterioration of capacitor characteristics can also be enhanced by the function of the wiring layer that eases an adverse effect of stress to the capacitor.

According to a second aspect of the present invention, the semiconductor memory device according to the first aspect further includes a plurality of word lines disposed on the memory cell array, which word lines constitute gates of the memory cell transistors, and shunt lines for the word lines, which shunt lines are formed of the first wiring layer. Since the word line shunt lines are formed of the first wiring layer, the resistance of the word lines can be reduced to realize speed-up, and simultaneously, the word line shunt lines become to have a hydrogen barrier effect for the capacitor, and an effect of reducing an adverse effect of stress to the capacitor. Thereby, the effect of suppressing deterioration of capacitor characteristics can be further increased by the wiring layer disposed above the capacitor, without specially providing word line shunt lines.

According to a third aspect of the present invention, in the semiconductor memory device according to the first aspect, the wirings formed of the first wiring layer are substantially arranged at minimum intervals of a layout rule. Therefore, the effect of suppressing deterioration of capacitor characteristics by the first wiring layer can be maximized by maximizing the density of the first wiring layer which is used as signal lines.

According to a fourth aspect of the present invention, in the semiconductor memory device according to the first aspect, plural bit lines disposed on the memory cell array include bit lines formed of the first wiring layer and bit lines formed of the second wiring layer. Therefore, the distance between adjacent bit lines can be increased, whereby an adverse effect of electrical interference between signal lines can be reduced to prevent malfunction during reading. Further, high-density arrangement of the bit lines can be realized, and the cell array area can be reduced when the cell array area is determined by the pitch of the bit lines.

According to a fifth aspect of the present invention, the semiconductor memory device according to the fourth aspect further includes shielded lines formed of the first wiring layer, each shielded line being disposed between two bit lines formed of the first wiring layer. Therefore, the area density of the first wiring layer can be easily increased. Further, electrical interference between the bit lines can be reduced, thereby obtaining an effect of preventing malfunction.

According to a sixth aspect of the present invention, in the semiconductor memory device according to the first aspect, signal lines formed of the first wiring layer on the memory cell array are shielded lines. Therefore, the area of the first wiring layer in the memory cell array can be further increased, thereby further enhancing the effect of suppressing deterioration of capacitor characteristics.

According to a seventh aspect of the present invention, the semiconductor memory device according to the first aspect further includes a third wiring layer formed above the second wiring layer, and plural bit lines being disposed on the memory cell array, which bit lines include bit lines formed of the first wiring layer and bit lines formed of the third wiring layer. Therefore, the distance between adjacent bit lines can be further increased, whereby the adverse effect of electrical interference between signal lines can be further reduced. Further, high-density arrangement of the bit lines can be realized, and the cell array area can be reduced when the cell array area is determined by the pitch of the bit lines.

According to an eighth aspect of the present invention, the semiconductor memory device according to the seventh aspect further includes plural word lines disposed on the memory cell array, which word lines constitute gates of the memory cell transistors, and shunt lines for the word lines, which shunt lines are formed of the second wiring layer. Since the word line shunt lines are formed of the second wiring layer, the resistance of the word lines can be reduced to realize speed-up, and simultaneously, the wiring structure using the second wiring layer as the shunt lines for the word lines can be realized.

According to a ninth aspect of the present invention, in the semiconductor memory device according to the first aspect, memory cell capacitors are ferroelectric capacitors. Therefore, a ferroelectric material that is reduced by a reduction atmosphere including hydrogen can be protected from the reduction atmosphere, and the effect of suppressing deterioration of capacitor characteristics becomes significant in the semiconductor memory device having the ferroelectric capacitors.

According to a tenth aspect of the present invention, the semiconductor memory device according to the first aspect further includes word lines constituting gates of the memory cell transistors, plate lines constituting first electrodes of the memory cell capacitors, and shunt lines for the word lines and shunt lines for the plate lines, which shunt lines for the word lines and for the plate lines are formed of the first wiring layer. Since the shunt lines for the plate lines which are first electrodes of the memory cell capacitors are formed of the first wiring layer, the plate line shunt lines become to have a hydrogen barrier effect for the capacitors, and an effect of reducing an adverse effect of stress to the capacitors. Thereby, the effect of suppressing deterioration of capacitor characteristics can be further enhanced by the wiring layer disposed above the capacitors without specially providing shunt lines for the plate lines. Further, voltage changes in the plate line can be carried out speedily and evenly by speed-up of the plate line that comes from reduction in its resistance as well as providing contacts between the plate line and the shunt line thereof at plural positions. As a result, the voltage generated in the plate lines can be more stabilized.

According to an eleventh aspect of the present invention, the semiconductor memory device according to the first aspect further includes a third wiring layer formed above the second wiring layer, plural word lines disposed on the memory cell array, which word lines constitute gates of the memory cell transistors, plate lines constituting first electrodes of the memory cell capacitors, shunt lines for the word lines and shunt lines for the plate lines, and plural bit lines disposed on the memory cell array, which bit lines include bit lines formed of the first wiring layer and bit lines formed of the third wiring layer which is positioned above the second wiring layer, and the word line shunt lines and the plate line shunt lines are formed of the second wiring layer. Therefore, the second wiring layer can be used as the shunt lines for the word lines. Furthermore, since the shunt lines for the plate lines are formed of the second wiring layer, speed-up is achieved by reduction in resistance of the plate lines, and voltage generated in the plate lines can be stabilized.

According to a twelfth aspect of the present invention, in the semiconductor memory device according to the first aspect, plural bit lines disposed on the memory cell array are positioned beneath the memory cell capacitors. Therefore, the memory cell capacitors can be disposed without being restricted by the contact parts of the bit lines and the diffusion layers, whereby the area occupied by the memory cells on the memory cell array can be reduced.

According to a thirteenth aspect of the present invention, the semiconductor memory device according to the twelfth aspect further includes plural shunt lines for the bit lines, which shunt lines include shunt lines formed of the first wiring layer and shunt lines formed of the second wiring layer. Therefore, the distance between adjacent bit line shunt lines can be increased, whereby an adverse effect of electrical interference between signal lines is reduced to prevent malfunction during reading. Further, it is possible to realize high-density arrangement of the bit line shunt lines, and reduction in the cell array area.

According to a fourteenth aspect of the present invention, the semiconductor memory device according to the thirteenth aspect further includes shielded lines formed of the first wiring layer, each shielded line being disposed between two bit line shunt lines which are formed of the first wiring layer. Therefore, the area density of the first wiring layer can be easily increased. Further, electrical interference between bit lines connected to adjacent bit line shunt lines can be reduced, thereby obtaining an effect of preventing malfunction.

According to a fifteenth aspect of the present invention, the semiconductor memory device according to the twelfth aspect further includes a third wiring layer formed above the second wiring layer, and plural shunt lines for the bit lines, which shunt lines include shunt lines formed of the first wiring layer and shunt lines formed of the third wiring layer. Therefore, the distance between adjacent bit line shunt lines can be increased, whereby an adverse effect of electrical interference between bit lines connected to the adjacent bit line shunt lines can be further reduced. Further, it is possible to realize high-density arrangement of the bit line shunt lines, and reduction in the cell array area.

According to a sixteenth aspect of the present invention, the semiconductor memory device according to the fifteenth aspect further includes plural word lines disposed on the memory cell array, which word lines constitute gates of the memory cell transistors, and shunt lines for the word lines, which baking wirings are formed of the second wiring layer. Therefore, speed-up can be achieved by reducing the resistance of the word lines, and simultaneously, a wiring structure utilizing the second wiring layer as word line shunt lines can be realized.

According to a seventeenth aspect of the present invention, the semiconductor memory device according to the twelfth aspect further includes a third wiring layer formed above the second wiring layer, plural word lines disposed on the memory cell array, said word lines constituting gates of the memory cell transistors, plate lines constituting first electrodes of the memory cell capacitors, and shunt lines for the bit lines, shunt lines for the word lines, and shunt lines for the plate lines, and the plural shunt lines for the bit lines include shunt lines formed of the first wiring layer, and shunt lines formed of the third wiring layer which is positioned above the second wiring layer, and the word line shunt lines and the plate line shunt lines are formed of the second wiring layer. Therefore, the second wiring layer can be used as the shunt lines for the word lines. Furthermore, since the shunt lines for the plate lines are formed of the second wiring layer, speed-up is achieved by reduction in resistance of the plate lines, and voltage generated in the plate lines can be stabilized.

According to an eighteenth aspect of the present invention, in the semiconductor memory device according to the first aspect, plural bit lines disposed on the memory cell array are positioned above the memory cell capacitors. Therefore, the distance from the memory cell capacitor to the diffusion layer is reduced, and moreover, the contact part of the memory cell capacitor and the diffusion layer can be arranged without being restricted by the bit lines, whereby formation of the capacitor contact part is facilitated.

According to a nineteenth aspect of the present invention, the semiconductor memory device according to the eighteenth aspect further includes shunt lines for the bit lines, and the bit lines are formed of the first wiring layer, and the shunt lines for the bit lines are formed of the second wiring layer. Therefore, the resistance of the bit lines formed of the first wiring layer can be reduced by the bit line shunt lines formed of the second wiring layer, resulting in speed-up of the device.

According to a twentieth aspect of the present invention, the semiconductor memory device according to the nineteenth aspect further includes shielded lines formed of the second wiring layer, each shielded line being disposed between two bit line shunt lines which are formed of the second wiring layer. Therefore, electrical interference between bit lines connected to adjacent bit line shunt lines can be reduced, thereby obtaining an effect of preventing malfunction. Further, when the memory cell capacitor is a ferroelectric memory, the parasitic capacitance of the bit lines can be optimized by disposing the shielded line between two bit line shunt lines.

According to a twenty-first aspect of the present invention, the semiconductor memory device according to the eighteenth aspect further includes a third wiring layer formed above the second wiring layer, and shunt lines for the bit lines, and the bit lines are formed of the first wiring layer while the bit line shunt lines are formed of the third wiring layer. Therefore, the resistance of the bit lines formed of the first wiring layer can be reduced by the bit line shunt lines formed of the third wiring layer, resulting in speed-up of the device.

According to a twenty-second aspect of the present invention, the semiconductor memory device according to the twenty-first aspect further includes plural word lines disposed on the memory cell array, which word lines constitute gates of the memory cell transistors, and shunt lines for the word lines, which shunt lines are formed of the second wiring layer. Therefore, speed-up can be achieved by reducing the resistance of word lines, and simultaneously, a wiring structure utilizing the second wiring layer as shunt lines for the word lines can be realized.

According to a twenty-third aspect of the present invention, the semiconductor memory device according to the eighteenth aspect further includes a third wiring layer formed above the second wiring layer, plural word lines disposed on the memory cell array, which word lines constitute gates of the memory cell transistors, plate lines constituting first electrodes of the memory cell capacitors, and shunt lines for the bit lines, shunt lines for the word lines, and shunt lines for the plate lines, wherein the bit lines are formed of the first wiring layer, the bit line shunt lines are formed of the third wiring layer positioned above the second wiring layer, and the word line shunt lines and plate line shunt lines are formed of the second wiring layer. Therefore, the second wiring layer can be used as the shunt lines for the word lines. Furthermore, since the shunt lines for the plate lines are formed of the second wiring layer, speed-up is achieved by reduction in resistance of the plate lines, and voltage generated in the plate lines can be stabilized.

### BRIEF DESCRIPTION OF THE DRAWINGS

FIG. 1 is a plan view for explaining a semiconductor memory device according to a first embodiment of the present invention.

FIG. 2 is a cross-sectional view taken along a line Ia-Ia in FIG. 1, illustrating a cross-sectional structure of the semiconductor memory device of the first embodiment in a word line direction.

FIG. 3 is a cross-sectional view taken along a line Ib-Ib in FIG. 1, illustrating a cross-sectional structure of the semiconductor memory device of the first embodiment in a bit line direction.

FIG. 4 is a diagram illustrating a cross-sectional structure of a semiconductor memory device in a word line direction according to a second embodiment of the present invention.

FIG. 5 is a diagram illustrating a cross-sectional structure of the semiconductor memory device of the second embodiment in a bit line direction.

FIG. 6 is a diagram illustrating a cross-sectional structure of a semiconductor memory device in a word line direction according to a third embodiment of the present invention.

FIG. 7 is a diagram illustrating a cross-sectional structure of the semiconductor memory device of the third embodiment in a bit line direction.

FIG. 8 is a diagram illustrating a cross-sectional structure of a semiconductor memory device in a word line direction according to a fourth embodiment of the present invention.

FIG. 9 is a diagram illustrating a cross-sectional structure of the semiconductor memory device of the fourth embodiment in a bit line direction.

FIG. 10 is a diagram illustrating a cross-sectional structure of a semiconductor memory device in a word line direction according to a fifth embodiment of the present invention.

FIG. 11 is a diagram illustrating a cross-sectional structure of the semiconductor memory device of the fifth embodiment in a bit line direction.

FIGS. 12(a)-12(i) are diagrams for explaining modifications of bit line structures applicable to the semiconductor memory device of the present invention, illustrating bit line structures in which bit lines are disposed above a memory cell array.

FIGS. 13(a)-13(k) are diagrams for explaining modifications of bit line structures applicable to the semiconductor memory device of the present invention, illustrating bit line structures in which bit lines are disposed beneath a memory cell array.

FIGS. 14(a)-14(c) are diagrams for explaining modifications of word line structures applicable to the semiconductor memory device of the present invention, illustrating a structure having no word line shunt lines (14(a)), a structure having word line shunt lines (14(b)), and another structure having word line shunt lines (14(c)).

FIGS. 15(a)-15(c) are diagrams for explaining modifications of plate line structures applicable to the semiconductor memory device of the present invention, illustrating a structure having no plate line shunt lines (15(a)), a structure having plate line shunt lines (15(b)), and another structure having plate line shunt lines (15(c)).

FIG. 16 is a diagram for explaining a conventional semiconductor memory device disclosed in a literature, illustrating a cross-sectional view of a main part of the semiconductor memory device in a bit line direction.

FIG. 17 is a diagram for explaining the conventional semiconductor memory device disclosed in the literature, illustrating a cross-sectional view of a main part of the semiconductor memory device in a word line direction.

### DETAILED DESCRIPTION OF THE PREFERRED EMBODIMENTS

### Embodiment 1

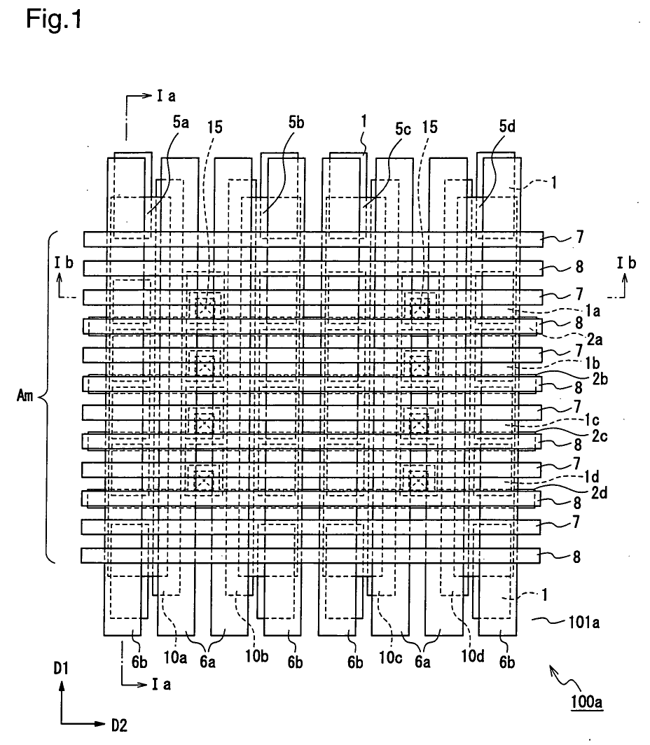

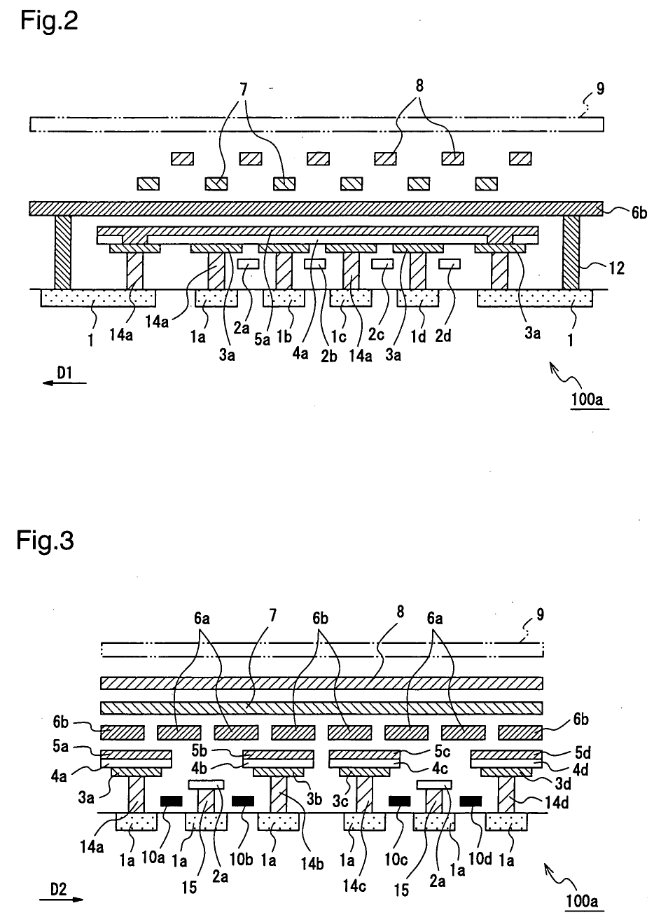

FIGS. 1 to 3 are diagrams for explaining a semiconductor memory device according to a first embodiment of the present invention. FIG. 1 is a plan view, FIG. 2 is a cross-sectional view taken along a line Ia-Ia in FIG. 1, and FIG. 3 is a cross-sectional view taken along a line Ib-Ib in FIG. 1.

The semiconductor memory device 100a according to the first embodiment has a structure in which a wiring layer is disposed above memory cell capacitors in order to improve a hydrogen barrier property for the capacitors and reduce an adverse effect due to stress applied to the capacitors, thereby realizing excellent capacitor characteristics.

More specifically, the semiconductor memory device 100a has, on a semiconductor substrate 101a, a memory cell array Am in which plural memory cell transistors and plural memory cell capacitors, which are components of memory cells, are arranged. In the memory cell array Am, plural word lines 10a˜10d extending along a first direction D1 intersect at right angles with plural bit lines 2a˜2d extending along a second direction D2.

More specifically, on the semiconductor substrate 101a of the semiconductor memory device 100a, plural diffusion layers 1a are disposed along the bit line 2a so that the diffusion layers are opposed to each other with the respective word lines 10a˜10b between them, and a portion of each word line between the opposed diffusion layers serves as a gate electrode of each memory cell transistor.

The diffusion layer 1a positioned between the adjacent word lines 10a and 10c and the diffusion layer 1a positioned between the word lines 10c and 10d are connected to the upper bit line 2a via a contact plug 15. Capacitor lower electrodes 3a and 3c as the components of the above-mentioned memory cell capacitors are disposed above the diffusion layers 1a positioned on the left side of FIG. 3 with respect to the word lines 10a and 10c, respectively, and the diffusion layers 1a are connected to the capacitor lower electrodes 3a and 3c via contact plugs 14a and 14c, respectively. Further, capacitor lower electrodes 3b and 3d as the components of the above-mentioned memory cell capacitors are disposed above the diffusion layers 1a positioned on the right side of FIG. 3 with respect to the word lines 10b and 10d, respectively, and the diffusion layers 1a are connected to the capacitor lower electrodes 3b and 3d via contact plugs 14b and 14d, respectively. Likewise, plural diffusion layers 1b arranged along the bit line 2b, plural diffusion layers 1c arranged along the bit line 2c, and plural diffusion layers 1d arranged along the bit line 2d are respectively opposed to each other with the word lines 10a˜10d between them, Like the diffusion layers 1a arranged along the bit line 2a, and a portion of the word line between the opposed diffusion layers serves as a gate electrode of each memory cell transistor. The diffusion layers 1b˜1d positioned between the adjacent word lines are connected to the upper bit lines 2b˜2d via contact plugs. Further, capacitor lower electrodes as the components of the memory cell capacitors are disposed above the diffusion layers 1b˜1d positioned outside the adjacent word lines, and these diffusion layers 1b˜1d are connected to the capacitor lower electrodes via contact plugs.

Moreover, on the plural capacitor lower electrodes 3a arranged along the word line direction D1, a capacitor ferroelectric film 4a as a component of the memory cell capacitors is disposed over these capacitor lower electrodes 3a, and a capacitor upper electrode 5a as a component of the memory cell capacitors is disposed on the capacitor ferroelectric film 4a. The capacitor upper electrode 5a comprises a plate line, and is connected to the lower capacitor electrode layer 3a via through holes that are formed through the capacitor ferroelectric film 4a at the both ends of the capacitor upper electrode 5a, and the capacitor lower electrode 3a is connected to a diffusion layer 1 positioned therebelow via the contact plug 14a. Likewise, on the plural capacitor lower electrodes 3b, 3c, and 3d arranged along the word line direction D1, capacitor ferroelectric films 4b, 4c, and 4d as the components of the memory cell capacitors are disposed over these capacitor lower electrodes, and capacitor upper electrodes 5b, 5c, and 5d as the components of the memory cell capacitors are disposed on the capacitor ferroelectric films 4b, 4c, and 4d. The capacitor upper electrodes 5b, 5c, and 5d are connected to the capacitor lower electrodes 3b, 3c, and 3d via through holes that are formed through the capacitor ferroelectric films 4b, 4c, and 4d at the both ends of each capacitor upper electrode, and the capacitor lower electrodes 3b, 3c, and 3d are connected to the diffusion layer 1 positioned therebelow via the contact plug.

In this first embodiment, the bit lines 2a˜2d comprise tungsten or a metal compound containing tungsten. The word lines 10a˜10d comprise polysilicon. Further, one memory cell transistor comprises a pair of diffusion layers that are opposed to each other with a word line between them, and a portion of the word line between the pair of diffusion layers, which is a gate electrode. For example, with reference to FIG. 3, one diffusion layer 1a disposed between the word line 10a and the word line 10b, and one diffusion layer 1a disposed on the left side of the word line 10a in the figure constitute one memory cell transistor, and one diffusion layer 1a disposed between the word line 10a and the word line 10b, and one diffusion layer 1a disposed on the right side of the word line 10b in the figure constitute one memory cell transistor. Accordingly, one diffusion layer positioned between the word line 10a and the word line 10b is shared by two memory cell transistors.

Word line shunt lines 6a and plate line shunt lines 6b, which extend along the word line direction D1, are disposed above the capacitor upper electrodes 5a˜5d, and each wiring comprises a first wiring layer. The word line shunt lines 6a are disposed so as to approximately overlap with the respective word lines 10a˜10d, and are connected to the corresponding word lines via contact plugs (not shown). The plate line shunt lines 6b are disposed so as to approximately overlap with the capacitor upper electrodes 5a˜5d, and portions thereof are connected to the diffusion layer 1 via the contact plug 12 (refer to FIG. 2).

Bit line backing lower wirings 7 which extend in the bit line direction D2 and comprise the second wiring layer are disposed above the word line shunt lines 6a and the plate line shunt lines 6b, and further, bit line backing upper wirings 8 which extend in the bit line direction D2 and comprise the third wiring layer are disposed on the bit line backing lower wirings 7. The bit lines 2a˜2d are electrically connected to either of the bit line backing lower wirings 7 and the bit line backing upper wirings 8. A shield layer 9 comprising the fourth wiring layer is spread over the entire memory cell array, above the bit line backing upper wirings 8a. The first to fourth wiring layers comprise aluminum or a metal compound containing copper.

In this first embodiment, the area occupied by the first wiring layer on the memory cell array Am is larger than the area occupied by the second wiring layer on the memory cell array. Further, the placement interval of the wirings comprising the first wiring layer is approximately the minimum value of the layout rule. Thereby, the hydrogen barrier property for the capacitors is improved, and adverse effects due to stress onto the capacitors are reduced, thereby suppressing degradation in capacitor characteristics.

Next, the function and effect will be described.

After evaluating residual polarization of a capacitor which represents an anti-reduction property, a semiconductor memory device in which only the first wiring layer is disposed on the memory cell array is compared with a semiconductor memory device in which only the second wiring layer is disposed on the memory cell array. The capacitor residual polarization is larger in the semiconductor memory device in which only the first wiring layer is disposed on the memory cell array than in the semiconductor memory device in which only the second wiring layer is disposed on the memory cell array. When these memory devices are compared with respect to the area dependency of the first wiring layer disposed on the memory cell array, it is clear that the larger the area is, the larger the capacitor residual polarization is. The reason is as follows. When the wiring density of the wiring layer closer to the capacitor is increased, the hydrogen barrier property for the capacitor is improved and an adverse effect due to stress applied to the capacitor is reduced. That is, in this first embodiment, as for the wiring layer on the capacitor, the area occupied by the first wiring layer on the memory cell array is made larger than the area occupied by the second wiring layer on the memory cell array, whereby the characteristics of the semiconductor memory device are significantly improved.

As described above, according to the first embodiment, since the area occupied by the first wiring layer on the memory cell array is made larger than the area occupied by the second wiring layer on the memory cell array, the capacitors can be further protected from being subjected to stress damages that occur above the memory cell array, and simultaneously, diffusion of hydrogen that causes reduction of the capacitor ferroelectric film can be further suppressed, whereby degradation in the capacitor characteristics can be easily minimized.

Further, since the word lines, the plate lines, and the bit lines are provided with shunt lines, high-speed operation of the semiconductor memory device can be achieved.

Furthermore, the first embodiment employs the multiple-layer structure of bit lines in which the bit line shunt lines are separated into the bit line backing lower wiring comprising the second wiring layer and the bit line backing upper wiring comprising the third wiring layer, and the bit lines are connected to either of the two bit line shunt lines. Therefore, adverse effects of electrical interference between different bit lines can be reduced, and the semiconductor memory device is prevented from malfunction at reading.

Furthermore, since in this first embodiment the word line shunt lines are composed of the first wiring layer, the word line shunt lines comprising not the second wiring layer that is far from the capacitors but the first wiring layer that is near to the capacitors serve as stress shield layers on the memory cell array. Thereby, it is unnecessary to provide another wiring layer different from the first wiring layer, for forming word line shunt lines, and the stress shielding effect for minimizing degradation in capacitor characteristics can be increased by the wiring layer disposed above the capacitors.

Furthermore, since in this first embodiment the bit lines are disposed beneath the memory cell capacitors, the memory cell capacitors can be disposed without being restricted by the positions of the contact parts between the bit lines and the diffusion layers, whereby the area occupied by the memory cells on the memory cell array is reduced.

Furthermore, since in this first embodiment the shunt line for the plate line which serves as an electrode of the memory cell capacitor comprises the first wiring layer, voltage changes in the plate line can be performed speedily and evenly by speed-up of the plate line that comes from reduction in its resistance by the shunt line as well as providing contacts between the plate line and the shunt line at plural positions, whereby the voltage generated in the plate line can be further stabilized.

While in this first embodiment the second wiring layer and the third wiring layer are used as wiring layers constituting the bit line shunt lines, these wiring layers may be used as wiring layers for constituting other signal lines, not being used as the bit line shunt lines.

Furthermore, with respect to the positional relationship between the signal lines comprising the first wiring layer and the capacitors, a positional relationship in which a larger part over the capacitors should be covered with signal lines, or in which signal lines should be disposed between adjacent capacitor upper electrodes, may be employed. This construction can suppress deterioration of capacitor characteristics more effectively.

Further, while in this first embodiment the specific wiring structure of the bit line underlying type including bit lines, word lines, and plate lines is described, the bit line underlying type wiring structure the present invention is applicable is not restricted thereto.

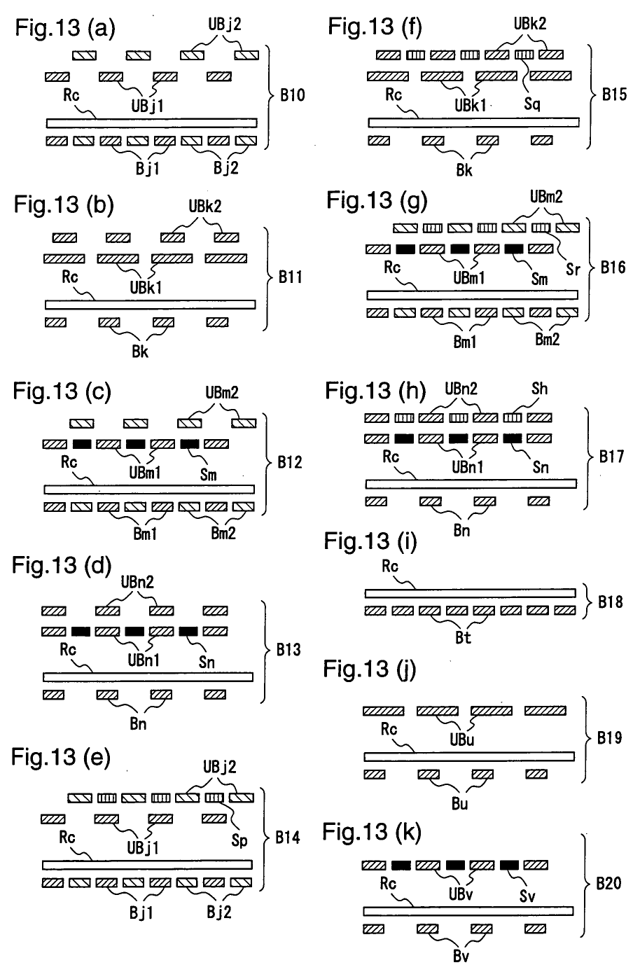

Hereinafter, various modifications of the first embodiment in which the layouts including the bit lines and their shunt lines are varied will be described with reference to FIGS. 13(a)˜13(k) showing cross-sectional views perpendicular to the bit line extending direction in the memory cell array, i.e., cross-sectional views taken along a line parallel to the direction D1 shown in FIG. 1.

(Modification 1)

A bit line structure B10 shown in FIG. 13(a) is a modification of the bit line structure of the first embodiment.

In a semiconductor memory device having the bit line structure B10, first and second bit lines Bj1 and Bj2 are alternately disposed beneath a capacitor region Rc disposed on a semiconductor substrate, and first bit line shunt lines UBj1 corresponding to the bit lines Bj1 and second bit line shunt lines UBj2 corresponding to the bit lines Bj2 are arranged above the capacitor region Rc. Thus, the bit line shunt lines UBj2 are made of a wiring layer that is located in a position higher than a wiring layer of the bit line shunt lines UBj1.

The first bit lines Bj1 and the second bit lines Bj2 substitute for the bit lines of the first embodiment, and the first bit line shunt lines UBj1 and the second bit line shunt lines UBj2 substitute for the bit line backing lower wirings 7 and the bit line backing upper wirings 8 of the first embodiment.

Further, the capacitor region Rc is the region where the memory capacitors are disposed, which is described for the first embodiment. The bit lines Bj1 and the bit lines Bj2 have different wiring layers constituting the corresponding bit line shunt lines. Further, the bit line shunt lines UBj1 and UBj2 are opposed to the corresponding bit lines Bj1 and Bj2, respectively. Accordingly, each bit line shunt line UBj2 is positioned on the area between the adjacent bit line shunt lines UBj1 so that the wiring UBj2 does not overlap with the wiring UBj1. Further, the bit lines Bj1 and the corresponding bit line shunt lines UBj1 are electrically connected, and the bit lines Bj2 and the corresponding bit line shunt lines UBj2 are electrically connected.

The wiring layer constituting the bit line shunt lines UBj1 is the first wiring layer having a relatively high wiring density on the memory cell array, and the wiring layer constituting the bit line shunt lines UBj2 is the second wiring layer having a relatively low density on the memory cell array. In this modification, the wiring layer constituting the plate line shunt lines 6b is a wiring layer other than the first and second wiring layers.

Although in this modification the bit line shunt lines UBj1 are constituted by the first wiring layer having a larger wiring density between the first and second wiring layers, the bit line shunt lines UBj1 may be constituted by a wiring layer other than the first and second wiring layers. Likewise, although the shunt lines UBj2 are constituted by the second wiring layer, the shunt lines UBj2 may be constituted by the first wiring layer or a wiring layer other than the first and second wiring layers.

(Modification 2)

A bit line structure B11 shown in FIG. 13(b) is a modification of the bit line structure according to the first embodiment.

In a semiconductor memory device having the bit line structure B11, bit lines Bk are disposed beneath the capacitor region Rc disposed on the semiconductor substrate, and first and second bit line shunt lines UBk1 and UBk2 corresponding to the bit lines Bk are disposed above the capacitor region Rc. Thus, the second bit line shunt lines UBk2 are constituted by a wiring layer that is located in a position higher than a wiring layer constituting the first bit line shunt lines UBk1.

The bit lines Bk are identical to the bit lines according to the first embodiment, and the first and second bit line shunt lines UBk1 and UBk2 substitute for the bit line backing lower wirings 7 and the bit line backing upper wirings 8, respectively.

Further, the capacitor region Rc is identical to that shown in FIG. 13(a). Each bit line Bk and the corresponding first bit line shunt line UBk1 are opposed to each other in the vertical direction, and the first bit line shunt line UBk1 corresponding to each bit line Bk and the second bit line shunt line UBk2 corresponding to the bit line Bk are opposed to each other in the vertical direction. Further, each bit line Bk and the corresponding first and second bit line shunt lines UBk1 and UBk2 are electrically connected.

The wiring layer constituting the first bit line shunt lines UBk1 is the first wiring layer having a relatively high wiring density on the memory cell array, and the wiring layer constituting the second bit line shunt lines UBk2 is the second wiring layer having a relatively low density on the memory cell array. In this modification, the wiring layer constituting the plate line shunt lines 6b is a wiring layer other than the first and second wiring layers.

Although in this modification the first bit line shunt lines UBk1 are constituted by the first wiring layer having the higher wiring density between the first and second wiring layers, the first bit line shunt lines UBk1 may be constituted by the second wiring layer having the lower wiring density, or a wiring layer other than the first and second wiring layers. Likewise, although the second bit line shunt lines UBk2 are constituted by the second wiring layer, the shunt lines UBk2 may be constituted by the first wiring layer or a wiring layer other than the first and second wiring layers.

(Modification 3)

A bit line structure B12 shown in FIG. 13(c) is a modification of the bit line structure according to the first embodiment.

In a semiconductor memory device having the bit line structure B12, first bit lines Bm1 and second bit lines Bm2 are alternately disposed beneath the capacitor region Rc disposed on the semiconductor substrate, and first bit line shunt lines UBm1 corresponding to the bit lines Bm1 and second bit line shunt lines UBm2 corresponding to the bit lines Bm2 are disposed above the capacitor area Rc. Thus, the bit line shunt lines UBm2 are constituted by a wiring layer located in a position higher than a wiring layer constituting the bit line shunt lines UBm2.

The first bit lines Bm1 and the second bit lines Bm2 substitute for the bit lines of the first embodiment, and the first bit line shunt lines UBm1 and the second bit line shunt lines UBm2 substitute for the bit line backing lower wirings 7 and the bit line backing upper wirings 8 of the first embodiment.

Further, the capacitor region Rc is identical to that shown in FIG. 13(a). The bit line shunt lines UBm1 and UBj2 are opposed to the corresponding bit lines Bm1 and Bm2, respectively. Accordingly, each bit line shunt line UBm2 is positioned on the area between the adjacent bit line shunt lines UBm1 so that the shunt line UBm2 does not overlap with the shunt line UBm1. Further, the bit lines Bm1 and the corresponding bit line shunt lines UBm1 are electrically connected, and the bit lines Bm2 and the corresponding bit line shunt lines UBm2 are electrically connected.

Further, in the bit line structure B12, another wiring Sm such as a shielded line is disposed between the adjacent bit line shunt lines UBm1. This shielded line substitutes for the shielded layer 9 of the first embodiment.

In this modification, the wiring layer constituting the bit line shunt lines UBm1 is the first wiring layer having a relatively high wiring density on the memory cell array, and the wiring layer constituting the bit line shunt lines UBm2 is the second wiring layer having a relatively low density on the memory cell array. Further, the wiring layer constituting the plate line shunt lines 6b is a wiring layer other than the first and second wiring layers.

Although in this modification the bit line shunt lines UBm1 are constituted by the first wiring layer, the bit line shunt lines UBm1 may be constituted by the second wiring layer or a wiring layer other than the first and second wiring layers. Likewise, although the bit line shunt lines UBm2 are constituted by the second wiring layer, the shunt lines UBm2 may be constituted by the first wiring layer or a wiring layer other than the first and second wiring layers.

(Modification 4)

A bit line structure B13 shown in FIG. 13(d) is a modification of the bit line structure according to the first embodiment.

In a semiconductor memory device having the bit line structure B13, bit lines Bn are disposed beneath the capacitor region Rc disposed on the semiconductor substrate, and first and second bit line shunt lines UBn1 and UBn2 corresponding to the bit lines Bn are disposed above the capacitor region Rc. Thus, the second bit line shunt lines UBn2 are constituted by a wiring layer that is located in a position higher than a wiring layer constituting the first bit line shunt lines UBn1.

The bit lines Bn are identical to the bit lines according to the first embodiment, and the first and second bit line shunt lines UBn1 and UBn2 substitute for the bit line backing lower wirings 7 and the bit line backing upper wirings 8, respectively.

Further, the capacitor region Rc is identical to that shown in FIG. 13(a). Each bit line Bn and the corresponding bit line shunt line UBn1 are opposed to each other in the vertical direction, and the bit line shunt line UBn1 corresponding to each bit line Bn and the bit line shunt line UBn2 corresponding to the bit line Bn are opposed to each other in the vertical direction. Further, each bit line Bn and the corresponding bit line shunt lines UBn1 and UBn2 are electrically connected.

Further, in the bit line structure B13, another wiring Sn such as a shielded line is disposed between the adjacent bit line shunt lines UBn1. This shielded line substitutes for the shielded layer 9 of the first embodiment.

The wiring layer constituting the bit line shunt lines UBn1 is the first wiring layer having a relatively high wiring density on the memory cell array, and the wiring layer constituting the bit line shunt lines UBn2 is the second wiring layer having a relatively low density on the memory cell array. In this modification, the wiring layer constituting the plate line shunt lines 6b is a wiring layer other than the first and second wiring layers.

Although in this modification the bit line shunt lines UBn1 are constituted by the first wiring layer, the bit line shunt lines UBn1 may be constituted by the second wiring layer, or a wiring layer other than the first and second wiring layers. Likewise, although the bit line shunt lines UBn2 are constituted by the second wiring layer, the shunt lines UBn2 may be constituted by the first wiring layer or a wiring layer other than the first and second wiring layers.

(Modification 5)

A bit line structure B14 shown in FIG. 13(e) is a modification of the bit line structure according to the first embodiment.

In a semiconductor memory device having the bit line structure B14, another wiring Sp such as a shielded line is disposed between the adjacent bit line shunt lines UBj2 in the bit line structure B10 shown in FIG. 13(a), and a wiring layer constituting the other wiring Sp is identical to the wiring layer constituting the bit line shunt lines UBj2. The constituents of the semiconductor memory device having the bit line structure B14 excluding the bit lines, the bit line shunt lines, and the other wirings are identical to those of the first embodiment.

(Modification 6)

A bit line structure B15 shown in FIG. 13(f) is a modification of the bit line structure according to the first embodiment.

In a semiconductor memory device having the bit line structure B15, another wiring Sq such as a shielded line is disposed between the adjacent bit line shunt lines UBk2 in the bit line structure B11 shown in FIG. 13(b), and a wiring layer constituting the other wiring Sq is identical to the wiring layer constituting the bit line shunt lines UBk2. The constituents of the semiconductor memory device having the bit line structure B15 excluding the bit lines, the bit line shunt lines, and the other wirings are identical to those of the first embodiment.

(Modification 7)

A bit line structure B16 shown in FIG. 13(g) is a modification of the bit line structure according to the first embodiment.

In a semiconductor memory device having the bit line structure B16, another wiring Sr such as a shielded line is disposed between the adjacent bit line shunt lines UBm2 in the bit line structure B12 shown in FIG. 13(c), and a wiring layer constituting the other wiring Sr is identical to the wiring layer constituting the bit line shunt lines UBm2. The constituents of the semiconductor memory device having the bit line structure B16 excluding the bit lines, the bit line shunt lines, and the other wirings are identical to those of the first embodiment.

(Modification 8)

A bit line structure B17 shown in FIG. 13(h) is a modification of the bit line structure according to the first embodiment.

In a semiconductor memory device having the bit line structure B17, another wiring Sh such as a shielded line is disposed between the adjacent bit line shunt lines UBn2 in the bit line structure B13 shown in FIG. 13(d), and a wiring layer constituting the other wiring Sh is identical to the wiring layer constituting the bit line shunt lines UBn2. The constituents of the semiconductor memory device having the bit line structure B17 excluding the bit lines, the bit line shunt lines, and the other wirings are identical to those of the first embodiment.

(Modification 9)

A bit line structure B18 shown in FIG. 13(i) is a modification of the bit line structure according to the first embodiment.

In the bit line structure B18, bit lines Bt are disposed beneath the capacitor region Rc disposed on the semiconductor substrate, and this structure B10 is obtained by removing the bit line shunt lines UBj1 and UBj2 which are positioned above the capacitor region Rc from the bit line structure B10 shown in FIG. 13(a).

In a semiconductor memory device having the bit line structure B18, the first and second wiring layers in the bit line structure B10, which are positioned above the capacitor region Rc, constitute wirings other than the bit lines and the bit line shunt lines, and the other constituents are identical to those of the first embodiment.

(Modification 10)

A bit line structure B19 shown in FIG. 13(j) is a modification of the bit line structure according to the first embodiment.

In a semiconductor memory device having the bit line structure B19, bit lines Bu are disposed beneath the capacitor region Rc disposed on the semiconductor substrate, and bit line shunt lines UBu corresponding to the bit lines Bu are disposed above the capacitor region Rc.

The bit lines Bu are identical to the bit lines of the first embodiment, and the bit line shunt lines UBu substitute for the bit line backing lower wirings 7 and the bit line backing upper wirings 8 of the first embodiment.

Further, the capacitor region Rc is identical to that shown in FIG. 13(a). Further, the bit lines Bu and the corresponding bit line shunt lines UBu are opposed to each other and are electrically connected with each other.

A wiring layer constituting the bit line shunt lines UBu is the first wiring layer whose wiring density on the memory cell array is higher than that of the second wiring layer which is positioned above the first wiring layer. Further, the wiring layer constituting the plate line shunt lines 6b is a wiring layer other than the first wiring layer.

Although in this modification the bit line shunt lines UBu are constituted by the first wiring layer, the bit line shunt lines UBu may be constituted by the second wiring layer whose wiring density is lower than that of the first wiring layer, or a wiring layer other than the first and second wiring layers.

(Modification 11)

A bit line structure B20 shown in FIG. 13(k) is a modification of the bit line structure according to the first embodiment.

In a semiconductor memory device having the bit line structure B20, bit lines By are disposed beneath the capacitor region Rc disposed on the semiconductor substrate, and bit line shunt lines UBv corresponding to the bit lines By are disposed above the capacitor region Rc, and further, another wiring Sv such as a shielded line is disposed between the adjacent bit line shunt lines UBv.

The bit lines By are identical to the bit lines of the first embodiment, the bit line shunt lines UBv substitute for the bit line backing lower wirings 7 and the bit line backing upper wirings 8 of the first embodiment, and the shielded line Sv substitutes for the shielded layer 9 of the first embodiment.

The capacitor region Rc is identical to that shown in FIG. 13(a). Further, the bit lines By and the corresponding bit line shunt lines UBv are opposed to each other and are electrically connected with each other.

The wiring layer constituting the bit line shunt lines UBv and the other wiring Sv such as a shielded line is the first wiring layer whose wiring density on the memory cell array is higher than that of the second wiring layer positioned above the first wiring layer. Further, the wiring layer constituting the plate line shunt lines 6b is a wiring layer other than the first and second wiring layers.

However, the bit line shunt lines UBv and the other wiring Sv are not restricted to those constituted by the first wiring layer. These wirings may be constituted by the second wiring layer whose wiring density is lower than that of the first wiring layer, or a wiring layer other than the first and second wiring layers.

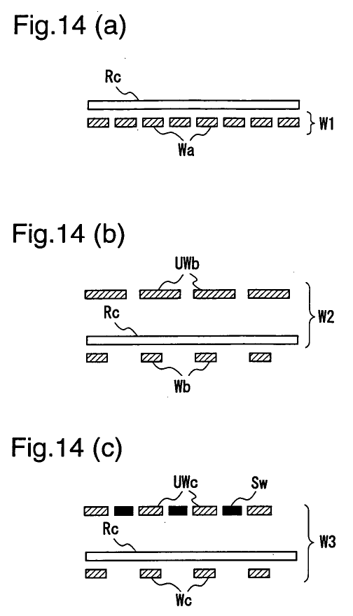

Next, various modifications in which the layouts of the word lines and their shunt lines of the first embodiment are varied will be described with reference to FIGS. 14(a) to 14(c). FIGS. 14(a) to 14(c) show cross-sectional views perpendicular to the word line extending direction in the memory cell array, that is, cross-sectional views taken along a line parallel to the direction D2 shown in FIG. 1.

(Modification 12)

A word line structure W1 shown in FIG. 14(a) is a modification of the word line structure according to the first embodiment.

In a semiconductor memory device having the word line structure W1, word lines Wa are arranged beneath the capacitor region Rc disposed on the semiconductor substrate, and there are provided no word line shunt lines corresponding to the word lines. The capacitor region Rc is identical to that shown in FIG. 13(a).

More specifically, the word line structure W1 is obtained by removing the word line shunt lines in the word line structure of the first embodiment, and the word lines Wa are identical to the word lines of the first embodiment.

In the semiconductor memory device having the word line structure W1, two wiring layers disposed above the capacitor region Rc, the upper layer having a wiring density higher than that of the lower layer, constitute wirings other than the word lines and the word line shunt lines, and the other constituents of the device are identical to those of the first embodiment.

(Modification 13)

A word line structure W2 shown in FIG. 14(b) is a modification of the word line structure according to the first embodiment.

In a semiconductor memory device having the word line structure W2, the word line shunt lines in the word line structure of the first embodiment are made of the first wiring layer, and the plate line shunt lines of the first embodiment are removed. The other constituents are identical to those of the first embodiment.

More specifically, in the word line structure W2, word lines Wb are disposed beneath the capacitor region Rc disposed on the semiconductor substrate, and word line shunt lines UWb corresponding to the word lines Wb are disposed above the capacitor region Rc. The capacitor region Rc is identical to that shown in FIG. 13(a).

The word lines Wb and the corresponding word line shunt lines UWb are opposed to each other and are electrically connected with each other.

The wiring layer constituting the word line shunt lines UWb is the first wiring layer whose wiring density on the memory cell array is higher than that of the second wiring layer positioned above the first wiring layer.

However, the word line shunt lines UWb are not restricted to those constituted by the first wiring layer, and the shunt lines UWb may be constituted by the second wiring layer whose wiring density is lower than that of the first wiring layer, or a wiring layer other than the first and second wiring layers. In this case, the bit line shunt lines 7 and 8 of the first embodiment must be constituted by a wiring layer other than these wiring layers.

(Modification 14)

A word line structure W3 shown in FIG. 14(c) is a modification of the word line structure of the first embodiment.

In a semiconductor memory device having the word line structure W3, the plate line shunt lines 6b of the first embodiment are replaced with wirings other than the plate line shunt lines, such as shielded lines Sw.

More specifically, in the word line structure W3, word lines Wc are disposed beneath the capacitor region Rc disposed on the semiconductor substrate, and word line shunt lines UWc corresponding to the word lines Wc are disposed above the capacitor region Rc, and further, another wiring Ws such as a shielded line is disposed between the adjacent word line shunt lines UWc.

The capacitor region Rc is identical to that shown in FIG. 13(a). Further, the word lines Wc and the corresponding word line shunt lines UWc are opposed to each other and are electrically connected with each other.

The wiring layer constituting the word line shunt lines UWc and the other wiring Sw such as a shielded line is the first wiring layer whose wiring density on the memory cell array is higher than that of the second wiring layer positioned on the first wiring layer.

However, the word line shunt lines UWc and the other wiring Sw are not restricted to those constituted by the first wiring layer, and these wirings may be constituted by the second wiring layer or a wiring layer other than the first and second wiring layers. In this case, the bit line shunt lines 7 and 8 of the first embodiment must be constituted by a wiring layer other than these wiring layers.

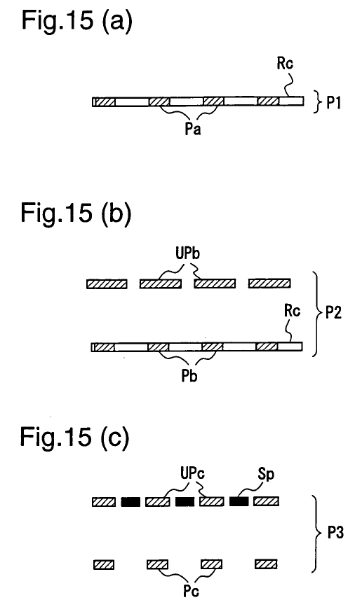

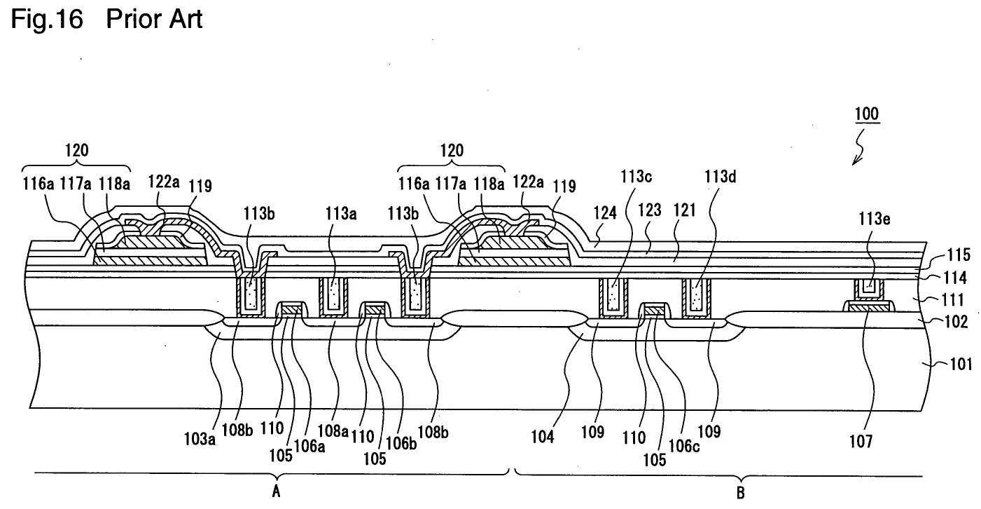

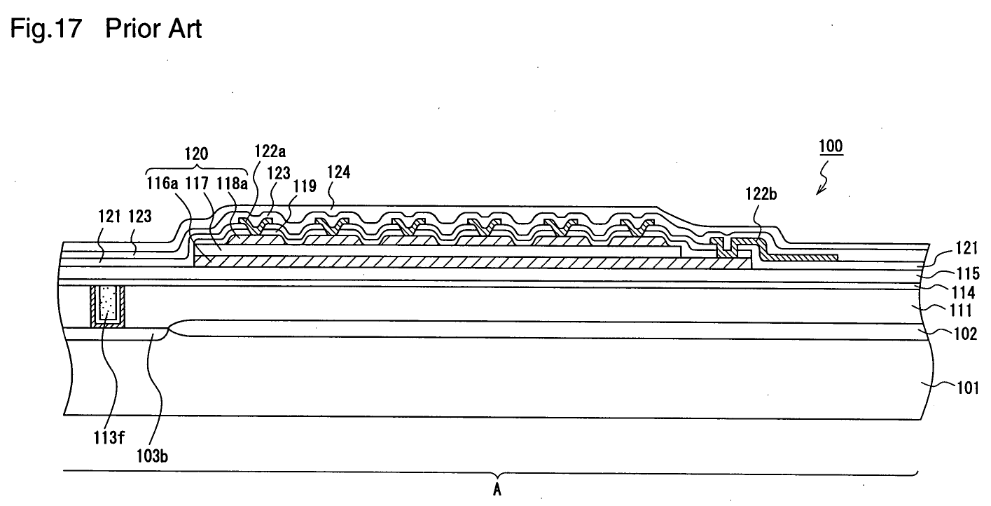

Next, various modifications in which the layouts of the plate lines and their shunt lines of the first embodiment are varied will be described with reference to FIGS. 15(a) to 15(c). FIGS. 15(a) to 15(c) show cross-sectional views perpendicular to the word line extending direction in the memory cell array, i.e., cross-sectional views taken along a line parallel to the direction D2 shown in FIG. 1.

(Modification 15)

A first plate line structure P1 shown in FIG. 15(a) is a modification of the plate line structure of the first embodiment.

A semiconductor memory device having the plate line structure P1 is obtained by removing the plate line shunt lines from the plate line structure of the first embodiment, and the other constituents are identical to those of the first embodiment.

More specifically, the plate line structure P1 has plate lines Pa positioned in the capacitor region Rc disposed on the semiconductor substrate, and there are no plate line shunt lines corresponding to the plate lines Pa. The plate lines Pa constitute, for example, upper electrodes of capacitors. The capacitor region Rc is identical to that shown in FIG. 13(a).

In the semiconductor memory device having the plate line structure P1, the two wiring layers positioned above the capacitor region Rc, the upper layer having a wiring density higher than that of the lower layer, constitute wirings other than the plate lines and the plate line shunt lines.

(Modification 16)

A plate line structure P2 shown in FIG. 15(b) is a modification of the plate line structure of the first embodiment.

A semiconductor memory device having the plate line structure P2 is obtained by removing the word line shunt lines of the first embodiment, and the other constituents are identical to those of the first embodiment.

To be specific, the plate line structure P2 includes plate lines Pb positioned in the capacitor region Rc disposed on the semiconductor substrate, and plate line shunt lines UPb positioned above the capacitor region Rc. The capacitor region Rc is identical to that shown in FIG. 13(a).

The plate lines Pb and the corresponding plate line shunt lines UPb are opposed to each other and are electrically connected with each other.

A wiring layer constituting the plate line shunt lines UPb is the first wiring layer whose wiring density on the memory cell array is higher than that of the second wiring layer positioned above the first wiring layer.

However, the plate line shunt lines UPb are not restricted to those constituted by the first wiring layer. The plate line shunt lines UPb may be constituted by the second wiring layer whose wiring density is lower than that of the first wiring layer, or a wiring layer other than the first and second wiring layers. In this case, the bit line shunt lines 7 and 8 of the first embodiment must be constituted by a wiring layer other than these wiring layers.

(Modification 17)

A third plate line structure P3 shown in FIG. 15(c) is a modification of the plate line structure of the first embodiment.

In a semiconductor memory device having the plate line structure P3, the word line shunt lines 6a of the first embodiment are replaced with other wirings Sp such as shielded lines, and the other constituents are identical to those of the first embodiment.

That is, the plate line structure P3 has plate lines Pc positioned in the capacitor region Rc disposed on the semiconductor substrate, plate line shunt lines UPc positioned above the capacitor region Rc, and other wirings Sp such as shielded lines disposed between the adjacent plate line shunt lines UPc. The capacitor region Rc is identical to that shown in FIG. 13(a).

The plate lines Pc are identical to the plate lines of the first embodiment, and the plate line shunt lines are identical to the plate line shunt lines UPc of the first embodiment, and the plate lines Pc and the corresponding plate line shunt lines UPc are opposed to each other and are electrically connected with each other.

The wiring layer constituting the plate line shunt lines UPc and the other wirings Sp such as shielded lines is the first wiring layer whose wiring density on the memory cell array is higher than that of the second wiring layer positioned above the first wiring layer.

However, the plate line shunt lines UPc and the other wirings Sp such as shielded lines are not restricted to those constituted by the first wiring layer. These wirings may be constituted by the second wiring layer whose wiring density is lower than that of the first wiring layer, or a wiring layer other than the first and second wiring layers. In this case, the bit line shunt lines 7 and 8 of the first embodiment must be constituted by a wiring layer other than these wiring layers.

As described above, the bit line structure of the first embodiment can be replaced with the modifications of the bit line structures shown in FIGS. 13(a) to 13(k), the word line structure of the first embodiment can be replaced with the modifications of the word line structures shown in FIGS. 14(a) to 14(c), and the plate line structure of the first embodiment can be replaced with the modifications of the plate line structures shown in FIGS. 15(a) to 15(c), and a semiconductor memory device that is preferable as the first embodiment of the present invention is realized by a combination of one of the plural bit line structures, one of the first to third word line structures, and one of the first to third plate line structures, according to the usage of the semiconductor memory device.

### Embodiment 2

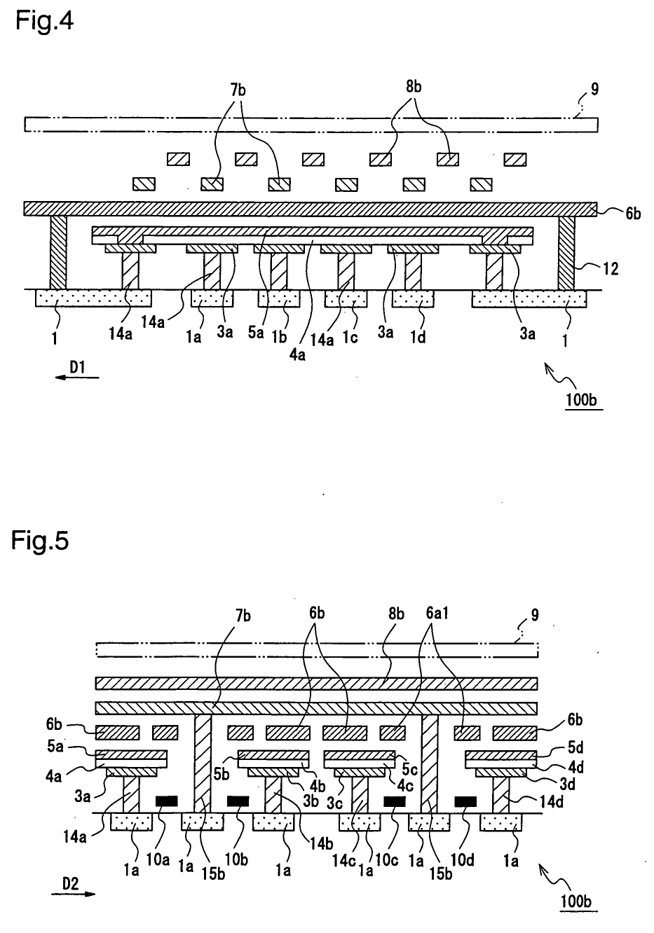

FIGS. 4 and 5 are diagrams for explaining a semiconductor memory device according to a second embodiment of the present invention. FIG. 4 is a cross-sectional view taken along a line parallel to the word line direction of the semiconductor memory device, and FIG. 5 is a cross-sectional view taken along a line parallel to the bit line direction of the semiconductor memory device.

The semiconductor memory device 100b of the second embodiment has a structure in which wiring layers are disposed above the memory cell capacitors so as to improve the hydrogen barrier property for the capacitors and reduce adverse effects due to stress applied onto the capacitors, as in the first embodiment. However, the bit line structure of this second embodiment is different from that of the first embodiment.

More specifically, in the first embodiment, the bit lines are disposed beneath the capacitors, and the bit line shunt lines are made of the second wiring layer and the third wiring layer. However, in this second embodiment, no bit lines are disposed beneath the capacitors, and diffusion layers 1a to 1d constituting memory cell transistors are connected through contact plugs 15b to either lower bit lines 7b comprising the second wiring layer or upper bit lines 8b comprising the third wiring layer. In FIG. 5, 6a1 denotes word line shunt lines disposed so as to overlap with the word lines, which correspond to the word line shunt lines 6a of the first embodiment. Further, in FIG. 5, diffusion layers connected to the upper bit lines 8b comprising the third wiring layer are not shown. The other constituents of the second embodiment are identical to those of the first embodiment.

In the second embodiment constructed as described above, since, like the first embodiment, the area occupied by the first wiring layer on the memory cell array is larger than the area occupied by the second wiring layer, the capacitors can be further protected from being subjected to stress damages that occur above the memory cell array, and simultaneously, diffusion of hydrogen that may cause reduction can be further suppressed, whereby deterioration of capacitor characteristics can be easily reduced.

Further, in this second embodiment, the diffusion layers 1a to 1d are connected, not to the bit lines disposed beneath the capacitors, but to the lower bit lines 7b comprising the second wiring layer or the upper bit lines 8b comprising the third wiring layer, which have resistance values lower than that of the bit lines. Therefore, in the semiconductor memory device 100b of the second embodiment, higher speed operation can be realized by the reduction in the resistance of the bit lines, as compared with the first embodiment. In addition, since the bit lines are constituted by different wiring layers, the distance between adjacent bit lines can be increased, thereby reducing the adverse effect of electrical interference between signal lines to prevent malfunction at reading.

While in this second embodiment the specific wiring structure of bit line overlying type, which includes the bit lines, word lines, plate lines, and shunt lines thereof, is described, the bit line overlying type wiring structure the present invention is applicable is not restricted thereto.

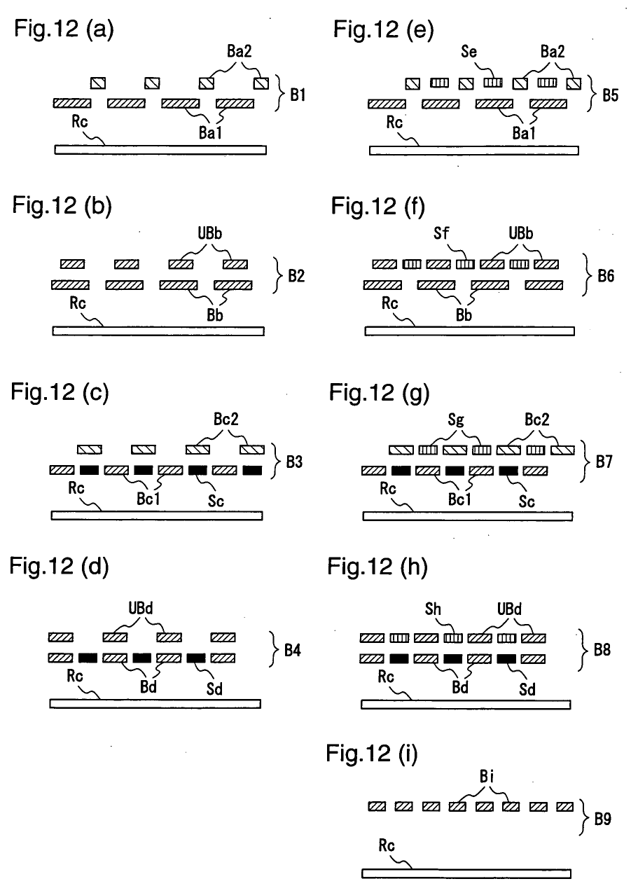

Hereinafter, various modifications of the second embodiment in which the layouts of the bit lines and their shunt lines are varied will be described with reference to FIGS. 12(a) to 12(i). FIGS. 12(a) to 12(i) show cross-sectional views perpendicular to the bit line extending direction in the memory cell array, i.e., cross-sectional views taken along a line parallel to the direction D1 shown in FIG. 1.

(Modification 1)

A first bit line structure B1 shown in FIG. 12(a) is a modification of the bit line structure of the second embodiment.

A semiconductor memory device having the bit line structure B1 is provided with first bit lines Ba1 and second bit lines Ba2 instead of the lower bit lines 7b and the upper bit lines 8b of the second embodiment, and the other constituents are identical to those of the second embodiment.

That is, in the bit line structure B1, first bit lines Ba1 and second bit lines Ba2 are disposed above the capacitor region Rc disposed on the semiconductor substrate, and the second bit lines Ba2 are made of a wiring layer that is located in a position higher than a wiring layer of the first bit lines Ba1.

The capacitor region Rc is a region where the memory cell capacitors described for the second embodiment are disposed. Further, each second bit line Ba2 is positioned on the area between the adjacent first bit lines Ba1 so that the second bit line Ba2 does not overlap with the first bit line Ba1. Further, the wiring layer constituting the first bit lines Ba1 and the wiring layer constituting the second bit lines Ba2 are the first wiring layer having a relatively high wiring density on the memory cell array, and the second wiring layer having a relatively low wiring density on the memory cell array, respectively. In the semiconductor memory device having the bit line structure B1, the plate line shunt lines 6b described for the second embodiment are removed.

Although in this modification the first bit lines Ba1 are constituted by the first wiring layer having a larger wiring density between the first and second wiring layers, the first bit lines Ba1 may be constituted by the second wiring layer having a lower wiring density or a wiring layer other than the first and second wiring layers. Likewise, although the second bit lines Ba2 are constituted by the second wiring layer, the second bit lines Ba2 may be constituted by the first wiring layer or a wiring layer other than the first and second wiring layers.

(Modification 2)

A bit line structure B2 shown in FIG. 12(b) is a modification of the bit line structure of the second embodiment.

In a semiconductor memory device having the bit line structure B2, bit lines Bb and bit line shunt lines UBb for the bit lines Bb are disposed above the capacitor region Rc disposed on the semiconductor substrate, and the bit line shunt lines UBb are constituted by a wiring layer that is located in a position higher than a wiring layer constituting the bit lines Bb.

The capacitor region Rc is identical to that shown in FIG. 12(a). The respective bit lines Bb and the corresponding bit line shunt lines UBb are opposed to each other and are electrically connected with each other. The bit lines Bb substitute for the lower bit lines 7b and the upper bit lines 8b of the second embodiment.

The wiring layer constituting the bit lines Bb and the wiring layer constituting the bit line shunt lines UBb are the first wiring layer having a relatively high wiring density on the memory cell array, and the second wiring layer having a relatively low wiring density on the memory cell array, respectively. In the semiconductor memory device having the bit line structure B2, the plate line shunt lines 6b described for the second embodiment are removed.

Although in this modification the bit lines Bb are constituted by the first wiring layer having a larger wiring density between the first and second wiring layers, the bit lines Bb may be constituted by the second wiring layer having a lower wiring density or a wiring layer other than the first and second wiring layers. Likewise, although the bit line shunt lines UBb are constituted by the second wiring layer, the bit line shunt lines UBb may be constituted by the first wiring layer or a wiring layer other than the first and second wiring layers.

(Modification 3)

A bit line structure B3 shown in FIG. 12(c) is a modification of the bit line structure of the second embodiment.

In a semiconductor memory device having the bit line structure B3, first bit lines Bc1 and second bit lines Bc2 are disposed above the capacitor region Rc disposed on the semiconductor substrate, and the second bit lines Bc2 are constituted by a wiring layer that is located in a position higher than a wiring layer constituting the first bit lines Bc1.

The first bit lines Bc1 and the second bit lines Bc2 substitute for the lower bit lines 7b and the upper bit lines 8b of the second embodiment. The capacitor region Rc is identical to that shown in FIG. 12(a). Each second bit line Bc2 is disposed on an area between adjacent first bit lines Bc1 so that the second bit line Bc2 does not overlap with the first bit line Bc1.

Further, in the bit line structure B3, another wiring Sc such as a shielded line is disposed between adjacent first bit lines Ba1. The shielded line Sc substitutes for the shielded layer 9 of the second embodiment.

The wiring layer constituting the first bit lines Bc1 and the wiring layer constituting the second bit lines Bc2 are the first wiring layer having a relatively high wiring density on the memory cell array, and the second wiring layer having a relatively low wiring density on the memory cell array, respectively. In the semiconductor memory device having the bit line structure B3, the plate line shunt lines 6b described for the second embodiment are removed.

Although in this modification the first bit lines Bc1 are constituted by the first wiring layer, the first bit lines Bc1 may be constituted by the second wiring layer or a wiring layer other than the first and second wiring layers. Likewise, although the second bit lines Bc2 are constituted by the second wiring layer, the second bit lines Bc2 may be constituted by the first wiring layer or a wiring layer other than the first and second wiring layers.

(Modification 4)

A bit line structure B4 shown in FIG. 12(d) is a modification of the bit line structure of the second embodiment.

In a semiconductor memory device having the bit line structure B4, bit lines Bd and bit line shunt lines UBd for the bit lines Bd are disposed above the capacitor region Rc disposed on the semiconductor substrate, and the bit line shunt lines UBd are constituted by a wiring layer that is located in a position higher than a wiring layer constituting the bit lines Bd.

The bit lines Bd substitute for the lower bit lines 7b and the upper bit lines 8b of the second embodiment. The capacitor region Rc is identical to that shown in FIG. 12(a), and the respective bit lines and the corresponding bit line shunt lines are opposed to each other and are electrically connected with each other. In the bit line structure B4, another wiring Sd such as a shielded line is disposed between adjacent bit lines Bd. The shielded line is identical to that of the bit line structure B3 shown in FIG. 12(c).

The wiring layer constituting the bit lines Bd and the wiring layer constituting the bit line shunt lines UBd are the first wiring layer having a relatively high wiring density on the memory cell array, and the second wiring layer having a relatively low wiring density on the memory cell array, respectively. In the semiconductor memory device having the bit line structure B4, the plate line shunt lines 6b described for the second embodiment are removed.

Although in this modification the bit lines Bd are constituted by the first wiring layer having a larger wiring density between the first and second wiring layers, the bit lines Bd may be constituted by the second wiring layer having a lower wiring density or a wiring layer other than the first and second wiring layers. Likewise, although the bit line shunt lines UBd are constituted by the second wiring layer, the bit line shunt lines UBd may be constituted by the first wiring layer or a wiring layer other than the first and second wiring layers.

(Modification 5)

A bit line structure B5 shown in FIG. 12(e) is a modification of the bit line structure of the second embodiment.

In a semiconductor memory device having the bit line structure B5, another wiring Se such as a shielded line is disposed between adjacent second bit lines Ba2 in the bit line structure B1 shown in FIG. 12(a), and a wiring layer constituting the other wiring Se is identical to the wiring layer constituting the second bit lines Ba2. The shielded line Se substitutes for the shielded line 9 of the second embodiment.

(Modification 6)

A bit line structure B6 shown in FIG. 12(f) is a modification of the bit line structure of the second embodiment.

In a semiconductor memory device having the bit line structure B6, another wiring Sf such as a shielded line is disposed between adjacent bit line shunt lines UBb in the bit line structure B2 shown in FIG. 12(b), and a wiring layer constituting the other wiring Sf is identical to the wiring layer constituting the bit line shunt lines UBb. The shielded line Sf substitutes for the shielded line 9 of the second embodiment.

(Modification 7)

A bit line structure B7 shown in FIG. 12(g) is a modification of the bit line structure of the second embodiment.

In a semiconductor memory device having the bit line structure B7, another wiring Sg such as a shielded line is disposed between adjacent second bit lines Bc2 in the bit line structure B3 shown in FIG. 12(c), and a wiring layer constituting the other wiring Sg is identical to the wiring layer constituting the second bit lines Bc2.

(Modification 8)

A bit line structure B8 shown in FIG. 12(h) is a modification of the bit line structure of the second embodiment.

In a semiconductor memory device having the bit line structure B8, another wiring Sh such as a shielded line is disposed between adjacent bit line shunt lines UBd in the bit line structure B4 shown in FIG. 12(d), and a wiring layer constituting the other wiring Sh is identical to the wiring layer constituting the bit line shunt line UBd.

(Modification 9)

A bit line structure B9 shown in FIG. 12(i) is a modification of the bit line structure of the second embodiment.

In a semiconductor memory device having the bit line structure B9, bit lines Bi are disposed above the capacitor region Rc disposed on the semiconductor substrate.

The bit lines Bi substitute for the lower bit lines and the upper bit lines of the second embodiment. The capacitor region Rc is identical to that shown in FIG. 12(a). The wiring layer constituting the bit lines Bi is the first wiring layer, between the first wiring layer having a relatively high wiring density on the memory cell array and the second wiring layer having a relatively low wiring density on the memory cell array. In the semiconductor memory device having the bit line structure B9, the plate line shunt lines 6b described for the second embodiment are removed.

However, the bit lines Bi are not restricted to those constituted by the first wiring layer. The bit lines Bi may be constituted by the second wiring layer or a wiring layer other than the first and second wiring layers.

Next, a description will be given of various modifications of the second embodiment in which the layouts of the word lines and their shunt lines are varied, with reference to FIGS. 14(a) to 14(c). FIGS. 14(a) to 14(c) show cross-sectional views perpendicular to the word line extending direction in the memory cell array, i.e., cross-sectional views taken along a line parallel to the direction D2 shown in FIG. 1.

(Modification 10)

A word line structure W1 shown in FIG. 14(a) is a modification of the word line structure of the second embodiment.

In a semiconductor memory device having the word line structure W1, word lines Wa are disposed beneath the capacitor region Rc disposed on the semiconductor substrate, and word line shunt lines corresponding to the word lines are not disposed. The capacitor region Rc is identical to that shown in FIG. 12(a).

To be specific, the word line structure W1 is obtained by removing the word line shunt lines 6a1 of the second embodiment, and the word lines Wa are identical to the word lines of the second embodiment.

In the semiconductor memory device having the word line structure W1, the two wiring layers positioned above the capacitor region Rc, the upper layer having a wiring density higher than that of the lower layer, constitute wirings other than the word lines and the word line shunt lines.

(Modification 11)

A word line structure W2 shown in FIG. 14(b) is a modification of the word line structure of the second embodiment.

In a semiconductor memory device having the word line structure W2, the word line shunt lines in the word line structure of the second embodiment are formed of a wiring layer other than the first and second wiring layers, and the other constituents are identical to those of the second embodiment.

To be specific, in the word line structure W2, word lines Wb are disposed beneath the capacitor region Rc disposed on the semiconductor substrate, and word line shunt lines UWb corresponding to the word lines Wb are disposed above the capacitor region Rc. The capacitor region Rc is identical to that shown in FIG. 12(a).

The word lines Wb and the corresponding word lines shunt lines UWb are opposed to each other and are electrically connected with each other. The word lines Wb are identical to the word lines of the second embodiment, and the word lines shunt lines UWb substitute for the word line shunt lines 6a1 of the second embodiment.

The wiring layer constituting the word line shunt lines UWb is the first wiring layer whose wiring density on the memory cell array is higher than that of the second wiring layer positioned on the first wiring layer.

The word line shunt lines UWb are not restricted to those constituted by the first wiring layer. The word line shunt lines UWb may be constituted by the second wiring layer whose wiring density is lower than that of the first wiring layer, or a wiring layer other than the first and second wiring layers.

(Modification 12)

A word line structure W3 shown in FIG. 14(c) is a modification of the word line structure of the second embodiment.

In a semiconductor memory device having the word line structure W3, the word line shunt lines in the word line structure of the second embodiment are formed of a wiring layer other than the first and second wiring layers, and another wiring Sw such as a shielded line is disposed between adjacent word line shunt lines. The other constituents are identical to those of the second embodiment.

More specifically, in the word line structure W3, word lines Wc are disposed beneath the capacitor region Rc disposed on the semiconductor substrate, and word line shunt lines UWc corresponding to the word lines Wc are disposed above the capacitor region Rc, and furthermore, another wiring Sw such as a shielded line is disposed between adjacent word line shunt lines UWc.

The capacitor region Rc is identical to that shown in FIG. 12(a). The word lines Wc and the corresponding word line shunt lines UWc are opposed to each other and are electrically connected with each other. The word lines Wc are identical to the word lines of the second embodiment, and the word line shunt lines UWc substitute for the word line shunt lines 6a1 of the second embodiment.

The wiring layer constituting the word line shunt lines UWc and the other wiring Sw such as a shielded line is the first wiring layer whose wiring density on the memory cell array is higher than that of the second wiring layer disposed on the first wiring layer.

However, the word line shunt lines UWc and the other wiring Sw are not restricted to those constituted by the first wiring layer. These wirings may be constituted by the second wiring layer whose wiring density is lower than that of the first wiring layer, or a wiring layer other than the first and second wiring layers.

Next, a description will be given of various modifications of the second embodiment in which the layouts of the plate lines and their shunt lines are varied, with reference to FIGS. 15(a) to 15(c). FIGS. 15(a) to 15(c) show cross-sectional views perpendicular to the word line extending direction in the memory cell array, i.e., cross-sectional views taken along a line parallel to the direction D2 shown in FIG. 1.

(Modification 13)

A first plate line structure P1 shown in FIG. 15(a) is a modification of the plate line structure of the first embodiment.

A semiconductor memory device having the plate line structure P1 is obtained by removing the plate line shunt lines 6b from the plate line structure of the second embodiment, and the other constituents of the semiconductor memory device having the plate line structure P1 are identical to those of the second embodiment.

More specifically, the plate line structure P1 has plate lines Pa positioned in the capacitor region Rc disposed on the semiconductor substrate, and there are no plate line shunt lines corresponding to the plate lines Pa. The plate lines Pa constitute, for example, upper electrodes of capacitors. The capacitor region Rc is identical to that shown in FIG. 12(a).

In the semiconductor memory device having the plate line structure P1, the two wiring layers positioned above the capacitor region Rc, the upper layer having a wiring density higher than that of the lower layer, constitute wirings other than the plate lines and the plate line shunt lines.

(Modification 14)

A plate line structure P2 shown in FIG. 15(b) is a modification of the plate line structure of the first embodiment.

A semiconductor memory device having the plate line structure P2 is obtained by removing the word line shunt lines 6a1 of the second embodiment, and the other constituents are identical to those of the second embodiment.

To be specific, the plate line structure P2 includes plate lines Pb positioned in the capacitor region Rc disposed on the semiconductor substrate, and plate line shunt lines UPb positioned above the capacitor region Rc. The capacitor region Rc is identical to that shown in FIG. 12(a).

The plate lines Pb and the corresponding plate line shunt lines UPb are opposed to each other and are electrically connected with each other. The plate lines Pb and the plate line shunt lines UPb are identical to the plate lines of the second embodiment.

A wiring layer constituting the plate line shunt lines UPb is the first wiring layer whose wiring density on the memory cell array is higher than that of the second wiring layer positioned above the first wiring layer.

However, the plate line shunt lines UPb are not restricted to those constituted by the first wiring layer. The plate line shunt lines UPb may be constituted by the second wiring layer whose wiring density is lower than that of the first wiring layer, or a wiring layer other than the first and second wiring layers.

(Modification 15)

A third plate line structure P3 shown in FIG. 15(c) is a modification of the plate line structure of the second embodiment.

In a semiconductor memory device having the plate line structure P3, the word line shunt lines of the second embodiment are replaced with other wirings Sp such as shielded lines.

The plate line structure P3 has plate lines Pc positioned in the capacitor region Rc disposed on the semiconductor substrate, plate line shunt lines UPc positioned above the capacitor region Rc, and other wirings Sp such as shielded lines disposed between the adjacent plate line shunt lines UPc. The capacitor region Rc is identical to that shown in FIG. 12(a).

The plate lines Pc and the plate line shunt lines UPc are identical to those of the second embodiment, and the plate lines Pc and the corresponding plate line shunt lines UPc are opposed to each other and are electrically connected with each other.

The wiring layer constituting the plate line shunt lines UPc and the other wirings Sp such as shielded lines is the first wiring layer whose wiring density on the memory cell array is higher than that of the second wiring layer positioned above the first wiring layer.

However, the plate line shunt lines UPc and the other wirings Sp such as shielded lines are not restricted to those constituted by the first wiring layer. These wirings may be constituted by the second wiring layer whose wiring density is lower than that of the first wiring layer, or a wiring layer other than the first and second wiring layers.

As described above, the bit line structure of the second embodiment can be replaced with the modifications of the bit line structures shown in FIGS. 12(a) to 12(k), the word line structure of the second embodiment can be replaced with the modifications of the word line structures shown in FIGS. 14(a) to 14(c), and the plate line structure of the second embodiment can be replaced with the modifications of the plate line structures shown in FIGS. 15(a) to 15(c), and a semiconductor memory device that is preferable as the second embodiment of the present invention is realized by a combination of one of the plural bit line structures, one of the first to third word line structures, and one of the first to third plate line structures, according to the usage of the semiconductor memory device.

### Embodiment 3

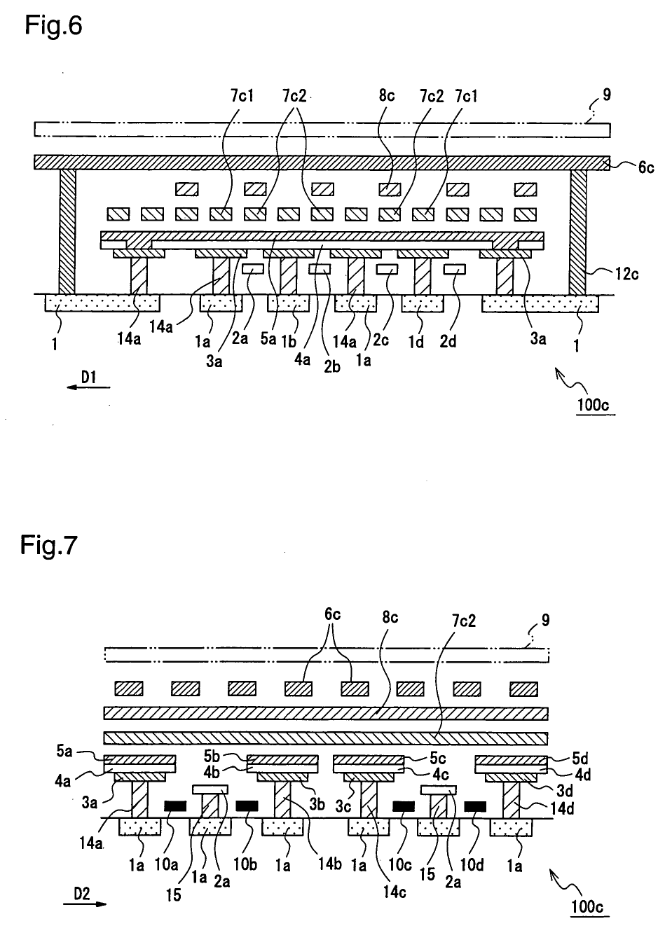

FIGS. 6 and 7 are diagrams for explaining a semiconductor memory device according to a third embodiment of the present invention. FIG. 6 is a cross-sectional view which is parallel to the word line direction of the semiconductor memory device, and FIG. 7 is a cross-sectional view which is parallel to the bit line direction of the semiconductor memory device.

The semiconductor memory device 100c of this third embodiment has a structure in which wiring layers are disposed above the memory cell capacitors so as to improve the hydrogen barrier property for the capacitors, and reduce adverse effects due to stress applied onto the capacitors, as in the first embodiment. However, this third embodiment is different from the first embodiment in the positional relationship between the plate line shunt lines and the bit line shunt lines.

To be specific, in the first embodiment, the word line shunt lines 6a and the plate line shunt lines 6b are formed of the first wiring layer, the bit line backing lower wirings 7 are formed of the second wiring layer, and the bit line backing upper wirings are formed of the third wiring layer. However, in this third embodiment, the plate line shunt lines 6c are formed of the third wiring layer, the bit line backing lower wirings 7c1 are formed of the first wiring layer, and the bit line backing upper wirings 8c are formed of the second wiring layer.

In this third embodiment, the wiring layers such as the shielded lines 7c2 are formed of the first wiring layer, and the multiple-layer wirings comprising the first and second wiring layers are constructed so that the area occupied by the first wiring layer on the memory cell array is larger than the area occupied by the second wiring layer.

Further, in this third embodiment, the bit line backing lower wirings 7c1 which extend along the bit line direction D2 and comprise the first wiring layer, and the shielded lines 7c2 which extend along the bit line direction D2 and comprise the first wiring layer are alternately disposed, and the shielded lines 7c2 are disposed so as to approximately overlap with the bit lines 2a to 2d beneath the capacitors. The line width of the bit line backing lower wirings 7c1 comprising the first wiring layer is nearly equal to that of the shielded lines 7c2 comprising the first wiring layer. Further, the bit line backing upper wirings 8c which extend in the bit line direction D2 and comprise the second wiring layer are positioned above the shielded lines 7c2.

In the third embodiment constructed as described above, since, like the first embodiment, the area occupied by the first wiring layer on the memory cell array is larger than the area occupied by the second wiring layer, the capacitors can be further protected from being subjected to stress damages that occur above the memory cell array, and simultaneously, hydrogen that may cause reduction is prevented from diffusing into the capacitor ferroelectric film, whereby deterioration of the capacitor characteristics can be easily suppressed.

Furthermore, in this third embodiment, the bit line shunt lines are separated into the bit line backing lower wirings 7c1 comprising the first wiring layer and the bit line backing upper wirings 8c comprising the second wiring layer, and the bit line backing lower wirings 7c1 and the bit line backing upper wirings 8c are disposed so as not to overlap with each other. Therefore, it is possible to minimize adverse effect of electrical interference between the different bit lines, i.e., the bit line connected to the bit line backing lower wiring 7c1 and the bit line connected to the bit line backing upper wiring 8c. Moreover, since the shielded line comprising the first wiring layer is disposed between the two bit line shunt lines comprising the first wiring layer, it is also possible to minimize adverse effect of electrical interference between the bit lines connected to the adjacent bit line backing lower wirings 7c1. Thereby, malfunction of the semiconductor memory device during reading can be reliably avoided.

Furthermore, since the memory cell capacitors are ferroelectric memories, it is possible to optimize the parasitic capacitance of the bit line by placing a shielded line between two bit line shunt lines.

While in this third embodiment the line width of the bit line backing lower wiring comprising the first wiring layer is nearly equal to that of the shielded line comprising the first wiring layer, the line widths of the bit line backing lower wiring and the shielded line are not restricted thereto.

For example, when the resistance of the bit line should be reduced, the line width of the bit line backing lower wiring 7c1 is desired to be made larger than that of the shielded line 7c2. Further, when the large bit line backing lower wiring 7c1 is disposed so as to cover as much area above the capacitor as possible, deterioration of the capacitor characteristics can be further suppressed. On the other hand, when the capacitance of the bit line should be reduced, the shielded line width may be larger than the bit line width.

Furthermore, while the third embodiment employs the bit line structure in which the bit lines are disposed beneath the capacitors and the bit line shunt lines are formed of the two wiring layers positioned above the capacitors as in the first embodiment, the third embodiment may employ the bit line structure in which no bit lines are disposed beneath the capacitors and the diffusion layers constituting the respective memory cell transistors are directly connected to either the bit lines comprising the first wiring layer disposed above the capacitors or the bit lines comprising the second wiring layers as in the second embodiment. In this case, the distance between adjacent bit lines can be increased, whereby adverse effect of electrical interference between signal lines can be reduced to prevent malfunction during reading. Further, high-density arrangement of bit lines is realized, and the cell array area can be reduced when the cell array area is determined by the pitch of the bit lines. In this case, since the shielded line formed of the first wiring layer is positioned between two bit lines formed of the first wiring layer, the area density of the first wiring layer can be easily increased, and moreover, electrical interference between bit lines can be reduced, resulting in an effect of preventing malfunction.

### Embodiment 4

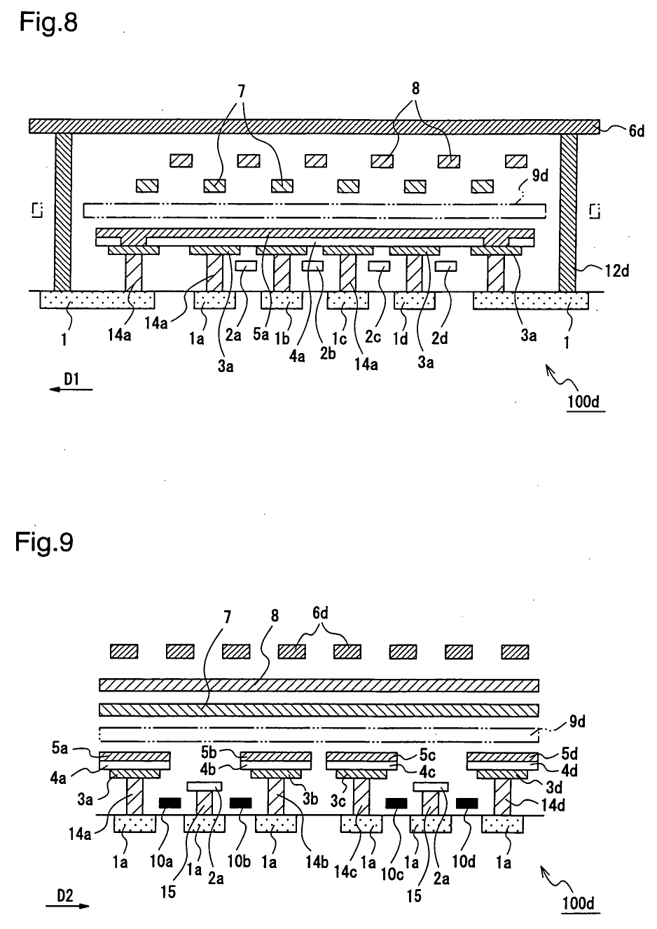

FIGS. 8 and 9 are diagrams for explaining a semiconductor memory device according to a fourth embodiment of the present invention. FIG. 8 is a cross-sectional view of the semiconductor memory device parallel to the word line direction, and FIG. 9 is a cross-sectional view of the semiconductor memory device parallel to the bit line direction.

The semiconductor memory device 100d of the fourth embodiment has the structure in which the wiring layers are disposed above the memory cell capacitors so as to improve the hydrogen barrier property for the capacitors, and reduce adverse effects due to stress applied to the capacitors, as in the first embodiment. In this fourth embodiment, however, the positional relationship between the shielded layer and the plate line shunt lines is different from that of the first embodiment.

More specifically, while in the first embodiment the word line shunt lines 6a and the plate line shunt lines 6b are formed of the first wiring layer and the shielded layer 9 is formed of the fourth wiring layer, in this fourth embodiment the plate line shunt lines 6d are formed of the fourth wiring layer and the shielded layer 9d is formed of the first wiring layer.

Further, in this fourth embodiment, the multiple-layer wirings comprising the first and second wiring layers are constructed so that the area occupied by the first wiring layer on the memory cell array is larger than the area occupied by the second wiring layer.

Furthermore, the shielded layer 9d is formed so as to cover the entire surface of the memory cell array.

In the fourth embodiment constructed as described above, since the area occupied by the first wiring layer on the memory cell array is larger than the area occupied by the second wiring layer as in the first embodiment, the capacitors can be further protected from being subjected to stress damages that occur above the memory cell array, and simultaneously, hydrogen that causes reduction is prevented from diffusing into the memory cell capacitors, whereby deterioration of the capacitor characteristics can be easily reduced.

Furthermore, since the shielded layer 9d is formed so as to cover the entire surface of the memory cell array, the ratio of the area occupied by the first wiring layer to the area occupied by the second wiring layer can be made larger in this fourth embodiment than in the first embodiment, whereby the effect of suppressing deterioration of the capacitor characteristics can be further increased.

While in this fourth embodiment the shielded layer is formed so as to cover the entire surface of the memory cell array, a plurality of linear shielded layers having a constant width may be disposed. Furthermore, a mesh shielded layer or a shielded layer having plural slits may be employed. The shielded layers of these structures are effective when the effect of stress to the capacitors due to the shielded layer becomes a problem.

Furthermore, when the shielded layer is divided into plural shielded lines, the respective shielded lines can be used as ground voltage signal lines or power supply voltage signal lines according to need.

Furthermore, while the fourth embodiment employs the bit line structure in which the bit lines are disposed beneath the capacitors and the bit line shunt lines are formed of the two wiring layers positioned above the capacitors as in the first embodiment, the third embodiment may employ the bit line structure in which no bit lines are disposed beneath the capacitors and the diffusion layers constituting the respective memory cell transistors are directly connected to either the bit lines comprising the first wiring layer disposed above the capacitors or the bit lines comprising the second wiring layers as in the second embodiment. In this case, the distance between adjacent bit lines can be increased, whereby adverse effect of electrical interference between signal lines can be reduced to prevent malfunction during reading. Further, high-density arrangement of bit lines is realized, and the cell array area can be reduced when the cell array area is determined by the pitch of the bit lines.

### Embodiment 5

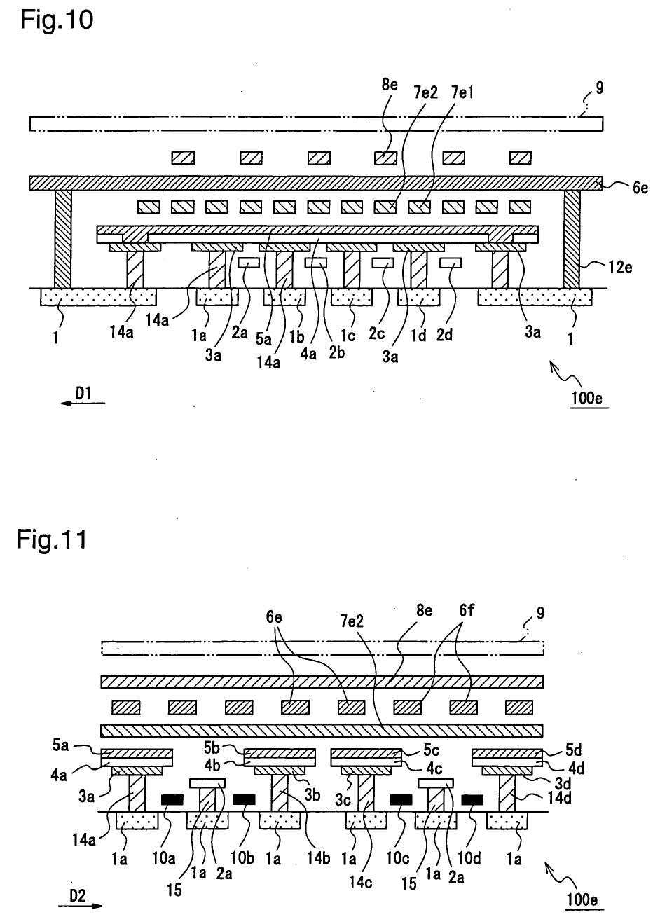

FIGS. 10 and 11 are diagrams for explaining a semiconductor memory device according to a fifth embodiment of the present invention. FIG. 10 is a cross-sectional view of the semiconductor memory device parallel to the word line direction, and FIG. 11 is a cross-sectional view of the semiconductor memory device parallel to the bit line direction.

In the semiconductor memory device 100e of this fifth embodiment, as in the first embodiment, the wiring layers are disposed above the memory cell capacitors so as to improve the hydrogen barrier property for the capacitors, and reduce adverse effects due to stress applied onto the capacitors. In this fifth embodiment, however, the positional relationship among the word line shunt lines, the plate line shunt lines, and the bit line shunt lines is different from that of the first embodiment.

More specifically, in the first embodiment, the word line shunt lines 6a and the plate line shunt lines 6b are formed of the first wiring layer, and the bit line shunt lines are formed of the second wiring layer and the third wiring layer. However, in this fifth embodiment, the word line shunt lines 6f and the plate line shunt lines 6e are formed of the second wiring layer, the bit line backing lower wiring 7e1 are formed of the first wiring layer, and the bit line backing upper wirings 8e are formed of the third wiring layer, and further, wiring layers such as the shielded lines 7e2 are formed of the first wiring layer.

In this fifth embodiment, the multiple-layer wirings comprising the first and second wiring layers are constituted such that the area occupied by the first wiring layer on the memory cell array is larger than the area occupied by the second wiring layer.

Moreover, in this fifth embodiment, the bit line backing lower wirings 7e1 which extend along the bit line direction D2 and comprise the first wiring layer, and the shielded lines 7e2 which extend along the bit line direction D2 and comprise the first wiring layer are alternately disposed, and the shielded lines 7e2 are disposed so as to approximately overlap with the bit lines 2a to 2d positioned beneath the capacitors. The line width of the bit line backing lower wirings 7e1 comprising the first wiring layer is nearly equal to that of the shielded lines 7e2 comprising the first wiring layer. Further, the bit line backing upper wirings 8e which extend in the bit line direction D2 and comprise the second wiring layer are positioned above the shielded lines 7e2.

In the fifth embodiment constructed as described above, since, like the first embodiment, the area occupied by the first wiring layer on the memory cell array is larger than the area occupied by the second wiring layer, the capacitors can be further protected from being subjected to stress damages that occur above the memory cell array, and simultaneously, hydrogen that may cause reduction is prevented from diffusing into the capacitor ferroelectric film, whereby deterioration of the capacitor characteristics can be easily suppressed.

Furthermore, in this fifth embodiment, the bit line shunt lines are separated into the bit line backing lower wirings 7e1 comprising the first wiring layer and the bit line backing upper wirings 8e comprising the third wiring layer, and the plate line shunt lines 6e and the word line shunt lines 6f are disposed between the bit line backing lower wirings 7e and the bit line backing upper wirings 8e. Therefore, it is possible to minimize adverse effect of electrical interference between the different bit lines, i.e., the bit line connected to the bit line backing lower wiring 7e1 and the bit line connected to the bit line backing upper wiring 8e, whereby malfunction of the semiconductor memory device during reading can be avoided.

Furthermore, since the bit line shunt lines include those formed of the first wiring layer and those formed of the third wiring layer located in a position higher than the second wiring layer, the second wiring layer can be used as shunt lines for the word lines. Moreover, since the second wiring layer is used as the shunt line layer for the plate lines of the memory cell capacitors, the voltage generated in the plate lines can be stabilized as in the first embodiment.

Furthermore, while the fifth embodiment employs the bit line structure in which the bit lines are disposed beneath the capacitors and the bit line shunt lines are formed of the two wiring layers positioned above the capacitors as in the first embodiment, the fifth embodiment may employ the bit line structure in which no bit lines are disposed beneath the capacitors and the diffusion layers constituting the respective memory cell transistors are directly connected to either the bit lines comprising the first wiring layer disposed above the capacitors or the bit lines comprising the third wiring layers as in the second embodiment. In this case, the distance between adjacent bit lines is increased, whereby adverse effect of electrical interference between adjacent bit lines can be further reduced. Further, high-density arrangement of bit lines is realized, and the cell array area can be reduced when the cell array area is determined by the pitch of the bit lines. Also in this case, since the word line shunt lines are formed of the second wiring layer, speed-up is achieved by lowering the resistance of the word lines, and simultaneously, a wiring structure utilizing the second wiring layer as the shunt lines for the word lines is realized.

Further, in the wiring structure which is obtained by changing the layout of the bit lines in the wiring structure of the fifth embodiment to the bit line overlying type wiring structure in which the bit lines are positioned above the capacitors as described above, the bit lines may be formed of the first wiring layer while the bit line shunt lines may be formed of the third wiring layer.

In this case, the resistance of the bit lines formed of the first wiring layer can be lowered by the bit line shunt lines formed of the third wiring layer, resulting in speed-up of the device.

Further, speed-up by reduction in the resistance of the word lines can be realized when the word line shunt lines are formed of the second wiring layer, in the bit line overlying type wiring structure in which the bit lines are formed of the first wiring layer and the bit line shunt lines are formed of the third wiring layer.

Moreover, when the word line shunt lines and the plate line shunt lines are formed of the second wiring layer in the above-mentioned bit line overlying type wiring structure, further speed-up can be achieved by reduction in the resistances of the word lines and the plate lines, and furthermore, the plate line voltage can be stabilized by reduction in the resistance of the plate lines.

The present invention is not restricted to the above-mentioned first to fifth embodiments, combinations of the above-mentioned embodiments are also within the scope of the present invention.

For example, a semiconductor memory device according to an embodiment of the present invention has a wiring structure obtained by combining the first embodiment and the fourth embodiment, in which the shielded layer 9 of the first embodiment is formed of the first wiring layer, and the plate line shunt lines 6b, the bit line backing lower wirings 7, and the bit line backing upper wirings 8 of the first embodiment are formed of the second, third, and fourth wiring layers, respectively. Further, a semiconductor memory device according to another embodiment of the present invention has a wiring structure obtained by combining the fourth embodiment and the fifth embodiment, in which the plate line shunt lines 6d of the fourth embodiment are formed of the third wiring layer, and the bit line backing upper wirings 8 of the fourth embodiment are formed of the fourth wiring layer.

While the respective embodiments mentioned above provide the wiring structure in which the first wiring layer, the second wiring layer, and the third wiring layer are successively disposed on the memory cell capacitors, the wiring structure on the memory cell capacitor may have another wiring layer between the memory cell capacitors and the first wiring layer, or between the first wiring layer and the second wiring layer, or between the second wiring layer and the third wiring layer. Further, another wiring layer may be disposed on the third wiring layer.

Although it is not specifically described in the respective embodiments, deterioration of the capacitors can be further restrained by arranging the wirings so as to minimize the part that is not covered with the wiring layers viewed in planar surface.

Furthermore, while in the above-mentioned embodiments a ferroelectric memory having a ferroelectric capacitor as a memory cell capacitor is described, a semiconductor memory device to which the present invention is applied is not restricted to the ferroelectric memory. The present invention can be similarly applied to a semiconductor memory having another capacitor structure or another capacitor material.

Moreover, it is needless to say that the modifications of the bit line structures, the modifications of the word line structures, and the modifications of the plate line structures according to the first embodiment are also applicable to the semiconductor memory devices according to the third to fifth embodiments.

### APPLICABILITY IN INDUSTRY

The semiconductor memory device according to the present invention can restrain deterioration of capacitor characteristics, and particularly, it is useful as a semiconductor memory device having a multiple-layer wiring on a memory array.

What is claimed is:

1. A semiconductor memory device having a memory cell array in which plural memory transistors and plural memory call capacitors, which are components of memory cells, are arranged, said device comprising:
a first wiring layer formed on the memory cell array; and
a second wiring layer formed above the first wiring layer;
wherein a wiring density of the first wiring layer on the memory cell array is higher than a wiring density of the second wiring layer on the memory cell array.

2. A semiconductor memory device as defined in claim 1 further including:
a plurality of word lines disposed on the memory cell array, said word lines constituting gates of the memory cell transistors; and
shunt lines for the word lines, said shunt lines being formed of the first wiring layer.

3. A semiconductor memory device as defined in claim 1 wherein the wirings formed of the first wiring layer are substantially arranged at minimum intervals of a layout rule.

4. A semiconductor memory device as defined in claim 1 wherein plural bit lines disposed on the memory cell array include bit lines formed of the first wiring layer and bit lines formed of the second wiring layer.

5. A semiconductor memory device as defined in claim 4 further including shielded lines formed of the first wiring layer, each shielded line being disposed between two bit lines formed of the first wiring layer.

6. A semiconductor memory device as defined in claim 1 wherein signal lines formed of the first wiring layer on the memory cell array are shielded lines.

7. A semiconductor memory device as defined in claim 1 further including:
a third wiring layer formed above the second wiring layer; and
plural bit lines being disposed on the memory cell array, said bit lines including bit lines formed of the first wiring layer and bit lines formed of the third wiring layer.

8. A semiconductor memory device as defined in claim 7 further including:
plural word lines disposed on the memory cell array, said word lines constituting gates of the memory cell transistors; and
shunt lines for the word lines, said shunt lines being formed of the second wiring layer.

9. A semiconductor memory device as defined in claim 1 wherein said memory cell capacitors are ferroelectric capacitors.

10. A semiconductor memory device as defined in claim 1 further including:
word lines constituting gates of the memory cell transistors;
plate lines constituting first electrodes of the memory cell capacitors; and
shunt lines for the word lines and shunt lines for the plate lines, said shunt lines for the word lines and for the plate lines being formed of the first wiring layer.

11. A semiconductor memory device as defined in claim 1 further including:
a third wiring layer formed above the second wiring layer;
plural word lines disposed on the memory cell array, said word lines constituting gates of the memory cell transistors;
plate lines constituting first electrodes of the memory cell capacitors;
shunt lines for the word lines and shunt lines for the plate lines;
plural bit lines disposed on the memory cell array, said bit lines including bit lines formed of the first wiring layer and bit lines formed of the third wiring layer which is positioned above the second wiring layer; and
said word line shunt lines and said plate line shunt lines being formed of the second wiring layer.

12. A semiconductor memory device as defined in claim 1 wherein plural bit lines disposed on the memory cell array are positioned beneath the memory cell capacitors.

13. A semiconductor memory device as defined in claim 12 further including:
plural shunt lines for the bit lines, said shunt lines including shunt lines formed of the first wiring layer and shunt lines formed of the second wiring layer.

14. A semiconductor memory device as defined in claim 13 further including shielded lines formed of the first wiring layer, each shielded line being disposed between two bit line shunt lines which are formed of the first wiring layer.

15. A semiconductor memory device as defined in claim 12 further including:
a third wiring layer formed above the second wiring layer; and
plural shunt lines for the bit lines, said shunt lines including shunt lines formed of the first wiring layer and shunt lines formed of the third wiring layer.

16. A semiconductor memory device as defined in claim 15 further including:
plural word lines disposed on the memory cell array, said word lines constituting gates of the memory cell transistors; and
shunt lines for the word lines, said baking wirings being formed of the second wiring layer.

17. A semiconductor memory device as defined in claim 12 further including:
a third wiring layer formed above the second wiring layer;
plural word lines disposed on the memory cell array, said word lines constituting gates of the memory cell transistors;
plate lines constituting first electrodes of the memory cell capacitors;
shunt lines for the bit lines, shunt lines for the word lines, and shunt lines for the plate lines;
said plural shunt lines for the bit lines including shunt lines formed of the first wiring layer, and shunt lines formed of the third wiring layer which is positioned above the second wiring layer; and
said word line shunt lines and said plate line shunt lines being formed of the second wiring layer.

18. A semiconductor memory device as defined in claim 1 wherein plural bit lines disposed on the memory cell array are positioned above the memory cell capacitors.

19. A semiconductor memory device as defined in claim 18 further including:
shunt lines for the bit lines;
said bit lines being formed of the first wiring layer; and
said shunt lines for the bit lines being formed of the second wiring layer.

20. A semiconductor memory device as defined in claim 19 further including shielded lines formed of the second wiring layer, each shielded line being disposed between two bit line shunt lines which are formed of the second wiring layer.

21. A semiconductor memory device as defined in claim 18 further including:
a third wiring layer formed above the second wiring layer;
shunt lines for the bit lines;
said bit lines being formed of the first wiring layer; and
said bit line shunt lines being formed of the third wiring layer.

22. A semiconductor memory device as defined in claim 21 further including:
plural word lines disposed on the memory cell array, said word lines constituting gates of the memory cell transistors; and
shunt lines for the word lines, said shunt lines being formed of the second wiring layer.

23. A semiconductor memory device as defined in claim 18 further including:
a third wiring layer formed above the second wiring layer;
plural word lines disposed on the memory cell array, said word lines constituting gates of the memory cell transistors;
plate lines constituting first electrodes of the memory cell capacitors;
shunt lines for the bit lines, shunt lines for the word lines, and shunt lines for the plate lines;
said bit lines being formed of the first wiring layer;
said bit line shunt lines being formed of the third wiring layer positioned above the second wiring layer; and
said word line shunt lines and plate line shunt lines being formed of the second wiring layer.
